(19) United States
(12) Patent Application Publication
(10) Pub. No.: US 2025/0079329 A1
(43) Pub. Date: Mar. 6, 2025

(54) ALIGNMENT STRUCTURES FOR DIE PICK-AND-PLACEMENT AND METHODS OF USING THE SAME

(71) Applicant: Taiwan Semiconductor Manufacturing Company Limited, Hsinchu (TW)

(72) Inventors: Jhih-Yu Wang, New Taipei City (TW); Po-Han Wang, Hsinchu City (TW); Yu-Hsiang Hu, Hsinchu City (TW); Hung-Jui Kuo, Hsinchu City (TW)

(21) Appl. No.: 18/456,567

(22) Filed: Aug. 28, 2023

(51) Int. Cl. H01L 23/544; H01L 21/56; H01L 23/31; H01L 23/538; H01L 25/10

(52) U.S. Cl. CPC H01L 23/544; H01L 21/561; H01L 21/568; H01L 23/3128; H01L 23/5383; H01L 23/5384; H01L 23/5385; H01L 25/105; H01L 24/16; H01L 24/32; H01L 24/73; H01L 2223/54426; H01L 2224/16235; H01L 2224/32225; H01L 2224/73204

(57) ABSTRACT

A fan-out package includes a molding compound die frame laterally surrounding at least one semiconductor die; and an organic interposer including redistribution dielectric layers embedding redistribution wiring interconnects and located on a first horizontal surface of the molding compound die frame. An alignment mark region including a localized recess region is located within an opening in a second horizontal surface of the molding compound die frame. The localized recess region extends from the second horizontal surface toward the organic interposer.

### BACKGROUND

Precise alignment of semiconductor dies and through-interposer via structures is desired to increase yield and reliability of packaging substrates.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top-down view of a first embodiment structure after formation of alignment mark structures in a first geometrical arrangement according to a first embodiment of the present disclosure.

FIG. 1B is a top-down view of the first embodiment structure after formation of alignment mark structures in a second geometrical arrangement according to the first embodiment of the present disclosure.

FIG. 1C is a vertical cross-sectional view of the first embodiment structure of FIG. 1A or FIG. 1B. Alignment mark structures are only schematically, and details of the alignment mark structures are not illustrated in FIG. 1C.

FIG. 1D is a vertical cross-sectional view of a unit area of a first configuration of the first embodiment structure of FIG. 1C.

FIG. 1E is a vertical cross-sectional view of a unit area of a second configuration of the first embodiment structure of FIG. 1C.

FIG. 2 is a vertical cross-sectional view of a unit area of the first configuration of the first embodiment structure after disposing semiconductor dies and through-interposer via (TIV) structures according to the first embodiment of the present disclosure.

FIG. 3 is a vertical cross-sectional view of a unit area of the first configuration of the first embodiment structure after formation of a molding compound matrix according to the first embodiment of the present disclosure.

FIG. 4 is a vertical cross-sectional view of a unit area of the first configuration of the first embodiment structure after formation of redistribution structures according to the first embodiment of the present disclosure.

FIG. 5 is a vertical cross-sectional view of a unit area of the first configuration of the first embodiment structure after attachment of a local interconnect die according to the first embodiment of the present disclosure.

FIG. 6 is a vertical cross-sectional view of a unit area of the first configuration of the first embodiment structure after attaching solder material portions to bonding structures according to the first embodiment of the present disclosure.

FIG. 7 is a vertical cross-sectional view of the first embodiment structure comprising a fan-out package according to the first embodiment of the present disclosure.

FIG. 8 is a vertical cross-sectional view of the first embodiment structure including an assembly of a fan-out package and a packaging substrate according to the first embodiment of the present disclosure.

FIG. 9 is a vertical cross-sectional view of the first embodiment structure after attaching an additional semiconductor die to the fan-out package according to the first embodiment of the present disclosure.

FIG. 10 is a vertical cross-sectional view of the first embodiment structure after attaching an assembly of the fan-out package, the packaging substrate, and the additional semiconductor die to a printed circuit board according to the first embodiment of the present disclosure.

FIG. 11 is a vertical cross-sectional view of a first alternative configuration of the first embodiment structure according to the first embodiment of the present disclosure.

FIG. 12 is a vertical cross-sectional view of a second alternative configuration of the first embodiment structure according to the first embodiment of the present disclosure.

FIG. 13 is a vertical cross-sectional view of a third alternative configuration of the first embodiment structure according to the first embodiment of the present disclosure.

FIG. 14 is a vertical cross-sectional view of a second embodiment structure after formation of a fan-out package according to a second embodiment of the present disclosure.

FIG. 15 is a vertical cross-sectional view of the second embodiment structure after formation of an assembly including the fan-out package, an additional semiconductor die, and a packaging substrate according to the second embodiment of the present disclosure.

FIG. 16 is a vertical cross-sectional view of the second embodiment structure after attaching a lid structure to the packaging substrate according to the second embodiment of the present disclosure.

FIG. 17 is a vertical cross-sectional view of the second embodiment structure after attaching an assembly including the fan-out package, the additional semiconductor die, the packaging substrate, and the lid structure to a printed circuit board according to the second embodiment of the present disclosure.

FIG. 18 is a vertical cross-sectional view of an alternative configuration of the second embodiment structure according to the second embodiment of the present disclosure.

FIG. 19 is a vertical cross-sectional view of a unit area of a third embodiment structure after formation of an alignment mark structure and a die attachment film according to a third embodiment of the present disclosure.

FIG. 20 is a vertical cross-sectional view of a unit area of the third embodiment structure after attachment of solder material portions to bonding structures according to the third embodiment of the present disclosure.

FIG. 21 is a vertical cross-sectional view of a unit area of the third embodiment structure after removal of a horizontally-extending portion of a die attachment film according to the third embodiment of the present disclosure.

FIG. 22 is a vertical cross-sectional view of the third embodiment structure comprising a fan-out package according to the third embodiment of the present disclosure.

FIG. 23 is a vertical cross-sectional view of the third embodiment structure after attaching the fan-out package to a packaging substrate, attaching an additional semiconductor die to the packaging substrate, and attaching an assembly of the fan-out package, the packaging substrate, and the additional semiconductor die to a printed circuit board according to the third embodiment of the present disclosure.

FIG. 24 is a vertical cross-sectional view of a first alternative configuration of the third embodiment structure according to the third embodiment of the present disclosure.

FIG. 25 is a vertical cross-sectional view of a second alternative configuration of the third embodiment structure according to the third embodiment of the present disclosure.

FIG. 26 is a vertical cross-sectional view of a third alternative configuration of the third embodiment structure according to the third embodiment of the present disclosure.

FIG. 27 is a vertical cross-sectional view of a unit area of a fourth embodiment structure after formation of an alignment mark structure and a die attachment film according to a fourth embodiment of the present disclosure.

FIG. 28 is a vertical cross-sectional view of a unit area of the fourth embodiment structure after attachment of solder material portions to bonding structures according to the fourth embodiment of the present disclosure.

FIG. 29 is a vertical cross-sectional view of the fourth embodiment structure comprising a fan-out package according to the fourth embodiment of the present disclosure.

FIG. 30 is a vertical cross-sectional view of the fourth embodiment structure after removal of a die attachment film and an alignment mark structure according to the fourth embodiment of the present disclosure.

FIG. 31 is a vertical cross-sectional view of the fourth embodiment structure after attaching the fan-out package to a packaging substrate, attaching an additional semiconductor die to the packaging substrate, and attaching an assembly of the fan-out package, the packaging substrate, and the additional semiconductor die to a printed circuit board according to the fourth embodiment of the present disclosure.

FIG. 32 is a vertical cross-sectional view of a first alternative configuration of the fourth embodiment structure according to the fourth embodiment of the present disclosure.

FIG. 33 is a vertical cross-sectional view of a second alternative configuration of the fourth embodiment structure according to the fourth embodiment of the present disclosure.

FIG. 34 is a flowchart illustrating steps for forming a device structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments of the present disclosure use alignment mark structures that are formed over a carrier wafer to align semiconductor dies during a pick-and-placement operation. Some embodiments may further optionally use through-interposer via structures during a pick-and-placement operation. The alignment mark structures may comprise metallic structures or dielectric structures. A molding compound matrix may be formed around the semiconductor dies and the optional through-interposer via structures. In some embodiments, a die attachment film may be provided between the alignment mark structures and the molding compound matrix. In some embodiments, the alignment mark structures may be removed after removal of the carrier wafer. The assembly of the semiconductor dies, the optional through-interposer via structures, and the molding compound matrix constitutes a reconstituted wafer, which may be diced to provide fan-out packages. The fan-out packages may be attached to a packaging substrate. In some embodiments an additional semiconductor die and/or a lid structure may optionally be attached to a fan-out package or to the packaging substrate. Alignment of at least one semiconductor die and optional through-interposer die structures may be improved through use of the alignment mark structures of the present disclosure during the pick-and-place operation, and the process yield and reliability of packaging substrates may be enhanced. Various aspects of the present invention are now described with reference to accompanying drawings.

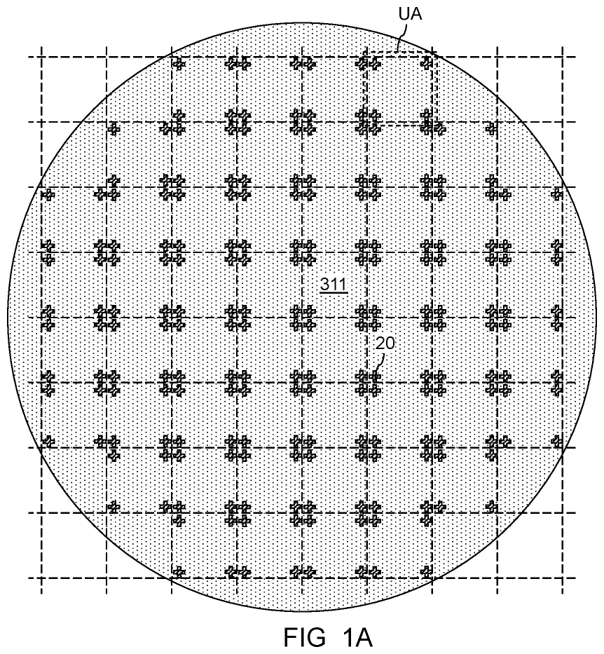

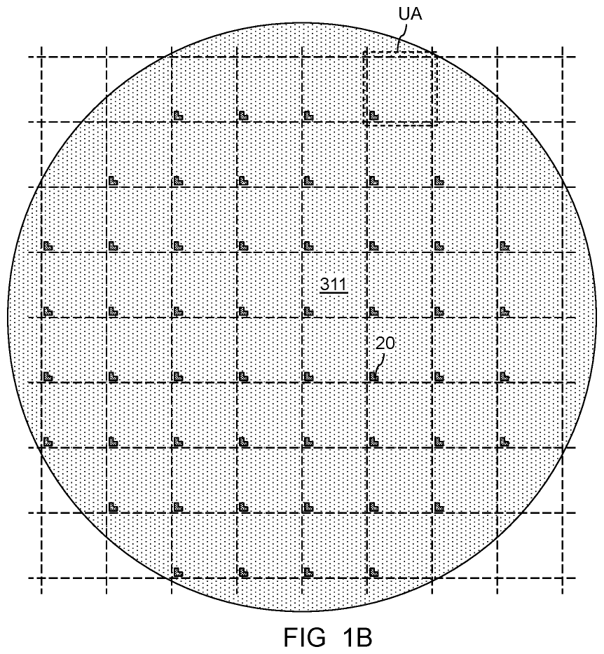

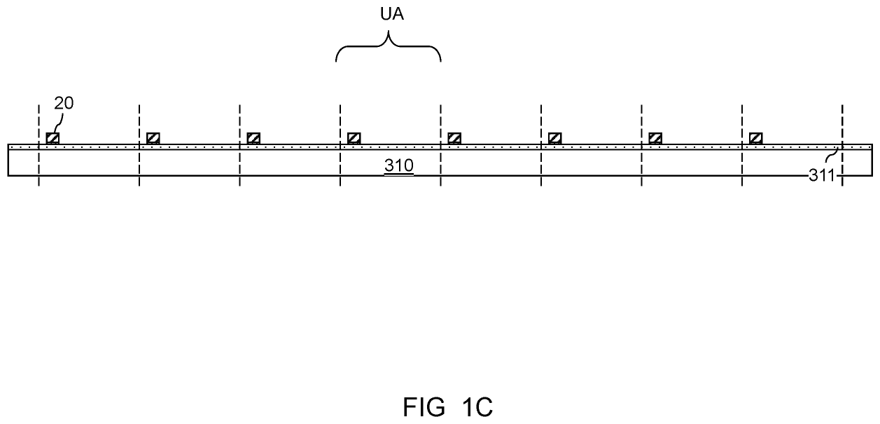

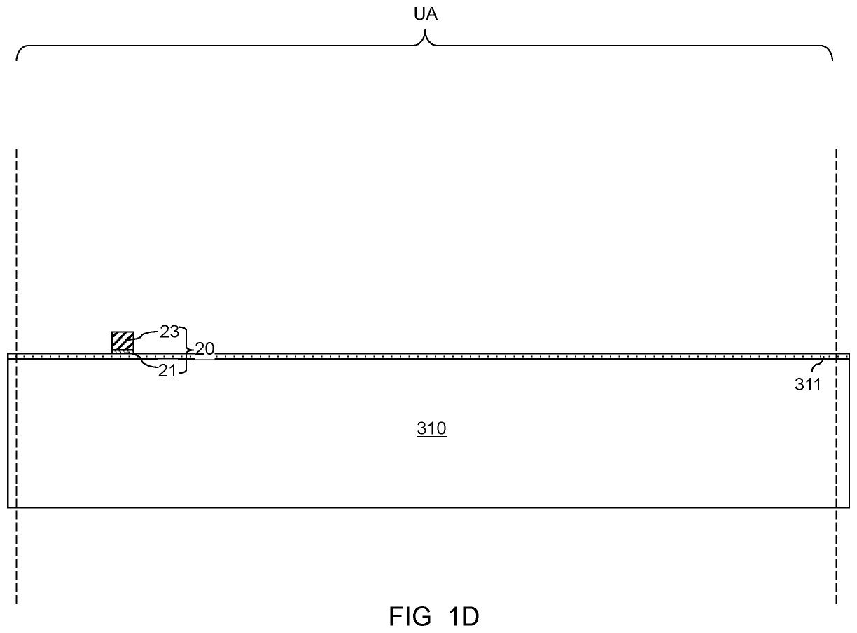

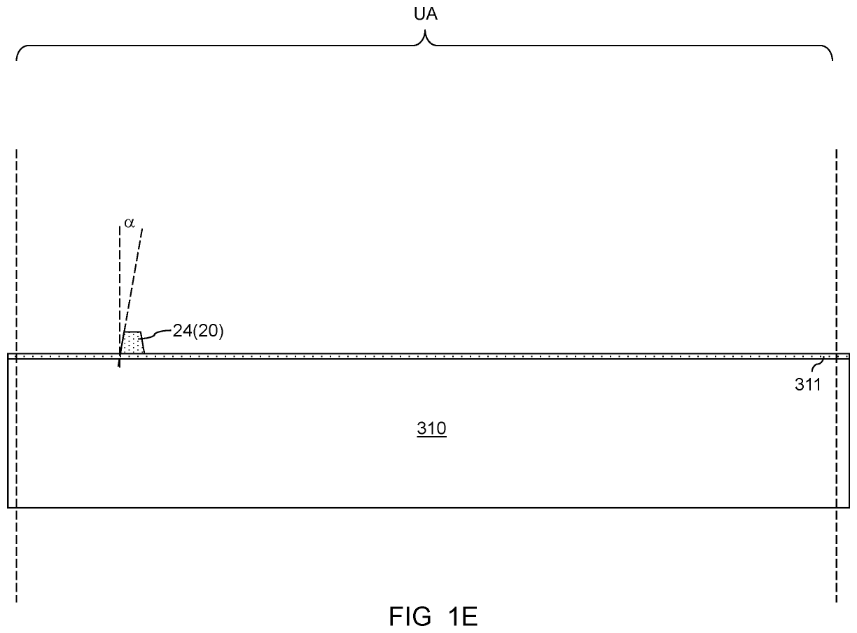

Referring to FIGS. 1A-1C, a structure according to a first embodiment of the present disclosure is illustrated. FIG. 1A is a top-down view of the first embodiment structure after formation of alignment mark structures 20 in embodiments in which the alignment mark structures 20 are in a first geometrical arrangement. FIG. 1B is a top-down view of the first embodiment structure after formation of alignment mark structures 20 in embodiments in which the alignment mark structures 20 are in a second geometrical arrangement. FIG. 1C is a vertical cross-sectional view of the first embodiment structure of FIG. 1A or FIG. 1B. Alignment mark structures are only schematically, and details of the alignment mark structures are not illustrated in FIG. 1C. As such, FIG. 1C illustrates only locations of the alignment mark structures, while FIGS. 1D and 1E illustrate structural details of the alignment mark structures.

The first embodiment structure illustrated in FIGS. 1A-1C comprises a carrier wafer 310. The carrier wafer 310 may comprise a semiconductor wafer, an insulator layer, a conductive wafer, or a composite wafer provided that the carrier wafer 310 provides sufficient mechanical strength to structures to be subsequently formed thereupon. In one embodiment, the carrier wafer 310 may comprise a transparent wafer such as a glass wafer or a sapphire wafer. The thickness of the carrier wafer 310 may be in a range from 500 microns to 2 mm, although lesser and greater thicknesses may also be used.

A light-to-heat conversion (LTHC) layer 311 may be formed on a top surface of the carrier wafer 310. The LTHC layer 311 comprises a material that absorbs light and convert it into heat. For example, suitable LTHC materials are commercially available. Generally, the LTHC layer 311 may be deposited by physical vapor deposition, chemical vapor deposition, or atomic layer deposition, and may have a thickness in a range from 10 nm to 1,000 nm, although lesser and greater thicknesses may also be used.

The area of the carrier wafer 310 may be include a two-dimensional array of unit areas UA in which a two-dimensional array of fan-out packages are to be subsequently formed. The two-dimensional array of unit areas UA may be arranged as a two-dimensional periodic array such as a two-dimensional rectangular array, or may be arranged as a two-dimensional irregular array in which the unit areas UA are repeated in a non-periodic manner. While the drawings of the present disclosure illustrate two-dimensional periodic arrays of unit areas UA, embodiments are expressly contemplated herein in which the unit areas UA are arranged as a non-periodic two-dimensional array.

According to an aspect of the present disclosure, a set of at least one alignment mark structure 20 may be formed within each of the unit areas UA. The relative position of the set of at least one alignment mark structure 20 may be the same for each of the unit areas UA. The set of at least one alignment mark structure 20 for each unit area may comprise a plurality of alignment mark structures 20 as illustrated in FIG. 1A (i.e., in some or all corners of the UA), or may consist of a single alignment mark structure 20 as illustrated in FIG. 1B (i.e., in a single corner of the UA). Generally speaking, the overall dimension of each alignment mark structure 20, such as a maximum dimension along each direction of repetition within a two-dimensional periodic array of unit areas UA, may be in a range from 20 microns to 300 microns, although lesser and greater overall dimensions may also be used for each alignment mark structure 20. The pattern of each alignment mark structure 20 may comprise any pattern that may be recognized as an orientable pattern (i.e., a non-circular pattern having azimuthal variations in lateral extent) by an optical system (e.g., camera) loaded with a pattern recognition program. For example, an alignment mark structure 20 may have a cross pattern illustrated in FIG. 1A, an L-shaped pattern illustrated in FIG. 1B, or any other orientable pattern known in the art. Features within a pattern of an alignment mark structure 20 may have dimensions that are recognizable by the optical system in a pick-and-place tool to be subsequently used. For example, an alignment mark structure 20 may have a minimum line width in a range from 2 microns to 50 microns depending on the optical resolution of the optical system. Generally, each alignment mark structure 20 may be formed in peripheral regions of a respective unit area UA such that the alignment mark structures 20 do not have any areal overlap with semiconductor dies that are to be subsequently placed over the carrier wafer 310.

According to an aspect of the present disclosure, the alignment mark structures 20 of the present disclosure may be formed by deposition and patterning of at least one material layer, which may comprise at least one metallic material layers or a dielectric material layer. FIG. 1D is a vertical cross-sectional view of a unit area of a first configuration of the first embodiment structure of FIG. 1C. FIG. 1E is a vertical cross-sectional view of a unit area of a second configuration of the first embodiment structure of FIG. 1C.

Referring to FIG. 1D, the first configuration of the first embodiment structure may be provided by depositing and patterning a layer stack of a plurality of metallic material layers (21, 23) to form the alignment mark structures 20. The plurality of metallic material layers (21, 23) may comprise a metallic adhesion promoter layer 21 and a metal layer 23. The metallic adhesion promoter layer 21 comprises a metal that provides high adhesion. For example, the metallic adhesion promoter layer 21 may comprise, and/or may consist essentially of, an elemental metal such as Ti, Ta, W, Co, a TiCu alloy, etc., and may have a thickness in a range from 5 nm to 100 nm, although lesser and greater thicknesses may also be used. The metal layer 23 comprises a metal that may be deposited with a high deposition rate, for example, by electroplating. The metal layer 23 may comprise copper, and may have a thickness in a range from 0.5 microns to 20 microns, such as from 1 micron to 10 microns, although lesser and greater thicknesses may also be used.

Each of the plurality of metallic material layers (21, 23) may be deposited as a blanket metallic material layer, i.e., as an un-patterned metallic material layer. A photoresist layer (not shown) may be applied over the plurality of metallic material layers (21, 23), and may be lithographically patterned to form discrete photoresist material portions. An anisotropic etch process may be performed to remove portions of the plurality of metallic material layers (21, 23) that are not masked by the discrete photoresist material portions. Patterned portions of the plurality of metallic material layers (21, 23) that underlie the discrete photoresist material portions constitute the alignment mark structures 20. The sidewalls of the alignment mark structures 20 may have a taper angle with respect to a vertical direction in a range from 0.1 degree to 10 degrees, such as from 0.2 degrees to 5 degrees, although lesser and greater taper angles may also be used. In this embodiment, each of the alignment mark structures 20 may have a variable horizontal cross-sectional area that decreases with a vertical distance from the carrier wafer 310. The photoresist layer may be subsequently removed, for example, by ashing. Each alignment mark structure 20 may comprise a layer stack of a metallic adhesion promoter layer 21 and a metal layer 23 with a horizontal interface therebetween.

Referring to FIG. 1E, the second configuration of the first embodiment structure may be provided by depositing and patterning a dielectric material layer to form the alignment mark structures 20. The dielectric material layer may comprise an organic material such as a polymer material, or an inorganic material such as silicon oxide, silicon nitride, silicon carbide, a dielectric metal oxide, or a layer stack of a plurality of inorganic dielectric material layers. The dielectric material layer may be formed, for example, by chemical vapor deposition or by spin coating. The thickness of the dielectric material layer may be in a range from 0.5 microns to 20 microns, such as from 1 micron to 10 microns, although lesser and greater thicknesses may also be used.

The dielectric material layer may be deposited as a blanket metallic material layer, i.e., as an un-patterned metallic material layer. A photoresist layer (not shown) may be applied over the dielectric material layer, and may be lithographically patterned to form discrete photoresist material portions. An anisotropic etch process may be performed to remove portions of the dielectric material layer that are not masked by the discrete photoresist material portions. Patterned portions of the dielectric material layer that underlie the discrete photoresist material portions constitute the alignment mark structures 20. In an alternative embodiment, a photosensitive dielectric material such as a photosensitive polymer material may be deposited, and may be patterned by lithographic exposure and development. In an illustrative example, polyimide may be used as the photosensitive polymer material. Remaining portions of the photosensitive dielectric material constitutes the alignment mark structures 20. In one embodiment, a curing process, such as an anneal process, may be performed after development of the photosensitive dielectric material. The sidewalls of the alignment mark structures 20 may have a taper angle α with respect to a vertical direction in a range from 1 degree to 20 degrees, such as from 3 degrees to 10 degrees, although lesser and greater taper angles may also be used. In this embodiment, each of the alignment mark structures 20 may have a variable horizontal cross-sectional area that decreases with a vertical distance from the carrier wafer 310. The photoresist layer may be subsequently removed, for example, by ashing. In embodiments in which the alignment mark structures 20 consist essentially of at least one dielectric material, the alignment mark structures 20 are referred to as dielectric alignment mark structures 24.

Generally, the alignment mark structures 20 described with reference to FIGS. 1D and 1E may have any horizontal cross-sectional shape as discussed with reference to FIGS. 1A-1C.

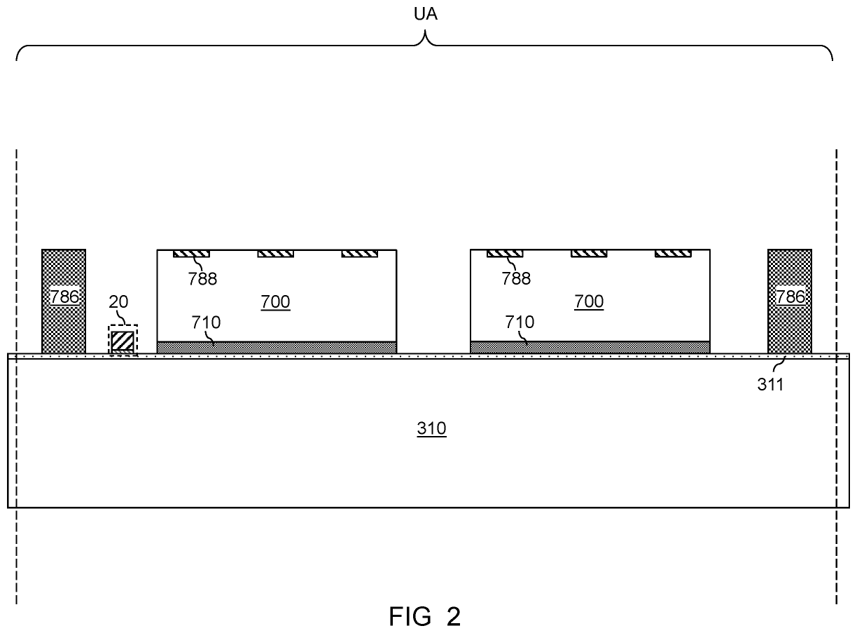

Referring to FIG. 2, a pick-and-placement tool including at least one optical system and a pattern recognition program may be used to dispose semiconductor dies 700 on the top surface of the LTHC layer 311. According to an aspect of the present disclosure, a set of at least one alignment mark structure 20 located within each unit area UA functions as a reference structure for determining the location for placement of each semiconductor die 700 that is placed within the respective unit area UA. In other words, each of the semiconductor dies 700 may be disposed over the carrier wafer 310 using a respective alignment mark structure 20 within a same unit area UA as a reference location for positioning the respective semiconductor die 700. In one embodiment, a die attachment film (DAF) 710 may be attached to a first side of each semiconductor die 700, and a second side of each semiconductor die 700 may be physically exposed. The second side of each semiconductor die 700 may comprise a respective array of bump structures, which is herein referred to as an array of on-die bump structures 788, i.e., bump structures that are located on a semiconductor die. The on-die bump structures 788 may comprise C4 bonding pads, or may comprise microbump structures (which are also referred to as C2 bump structures). Each combination of a semiconductor die 700 and a DAF 710 may be disposed on the LTHC layer 311 such that the DAF 710 directly contacts a top surface of the LTHC layer 311. The thickness of each DAF 710 may be in a range from 1 micron to 20 microns, such as from 2 microns to 6 microns, although lesser and greater thicknesses may also be used.

Optionally, through-interposer via (TIV) structures 786 may be disposed on the top surface of the LTHC layer 311. The same pick-and-placement tool or a different pick-and-placement tool may be used to dispose the TIV structures 786 within each unit area. According to an aspect of the present disclosure, a set of at least one alignment mark structure 20 located within each unit area UA functions as a reference structure for determining the location for placement of each TIV structure 786 that is placed within the respective unit area UA. In other words, each of the TIV structures 786 may be disposed over the carrier wafer 310 using a respective alignment mark structure 20 within a same unit area UA as a reference location for positioning the respective TIV structure 786. Optionally, additional die attachment films (not illustrated) may be used to assist placement of the TIV structures 786 on the LTHC layer 311. In such embodiments, the additional die attachment films may be positioned between the TIV structures 786 and the LTHC layer 311. Generally, the TIV structures 786 comprise at least one metallic material (such as copper or tungsten), and may have cylindrical shapes or shapes of a respective frustum. The lateral dimension of each TIV structure 786 may be in a range from 5 microns to 60 microns, such as from 10 microns to 30 microns, although lesser and greater dimensions may also be used. The height of the TIV structures 786 may be about the same as the height of the semiconductor dies 700. Generally, the top surfaces of the TIV structures 786 may be located within a same horizontal plane as the top surfaces of the semiconductor dies 700. The height, i.e., the thickness, of each semiconductor die 700 may be in a range from 30 microns to 300 microns, although lesser and greater thicknesses may also be used.

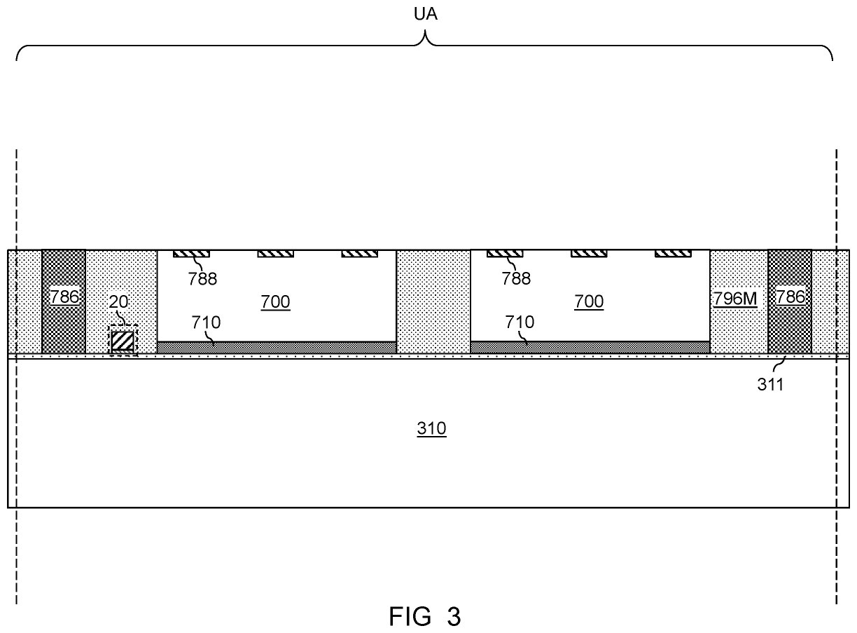

Referring to FIG. 3, a molding compound (MC) may be applied to the gaps between the semiconductor dies 700 and the TIV structures 786. The MC includes an epoxy-containing compound that may be hardened (i.e., cured) to provide a dielectric material portion having sufficient stiffness and mechanical strength. The MC may include epoxy resin, hardener, silica (as a filler material), and other additives. The MC may be provided in a liquid form or in a solid form depending on the viscosity and flowability. Liquid MC typically provides better handling, good flowability, less voids, better fill, and less flow marks. Solid MC typically provides less cure shrinkage, better stand-off, and less die drift. A high filler content (such as 85% in weight) within an MC may shorten the time in mold, lower the mold shrinkage, and reduce the mold warpage. Uniform filler size distribution in the MC may reduce flow marks, and may enhance flowability.

The MC may be cured at a curing temperature to form an MC matrix, which is herein referred to as a molding compound (MC) matrix 796M. The MC matrix 796M laterally encloses each of the semiconductor dies 700 and the TIV structures 786. The MC matrix 796M may be a continuous material layer that extends across the entirety of the area of a reconstituted wafer overlying the carrier wafer 310. Excess portions of the MC matrix 796M may be removed from above the horizontal plane including the top surfaces of the semiconductor dies 700 and the TIV structures 786 by a planarization process, which may use chemical mechanical planarization (CMP). Top surfaces of the semiconductor dies 700 and the TIV structures 786 may be physically exposed after performing the planarization process. The top surfaces of the semiconductor dies 700 and the TIV structures 786 may be located within a horizontal plane including the top surface of the MC matrix 796M.

The MC matrix 796M includes a plurality of molding compound (MC) interposer frames located within a respective unit area UA. Each MC interposer frame corresponds to a portion of the MC matrix 796M located within a unit area UA, i.e., an area of a single interposer to be subsequently formed. In other words, each portion of the MC matrix 796M that is located within a respective unit area UA constitutes an MC interposer frame. The MC interposer frames are laterally adjoined to one another to provide a unitary structure, which is the MC matrix 796M. Each MC interposer frame laterally surrounds a respective set of at least one semiconductor die 700, and may laterally surround a respective array of TIV structures 786.

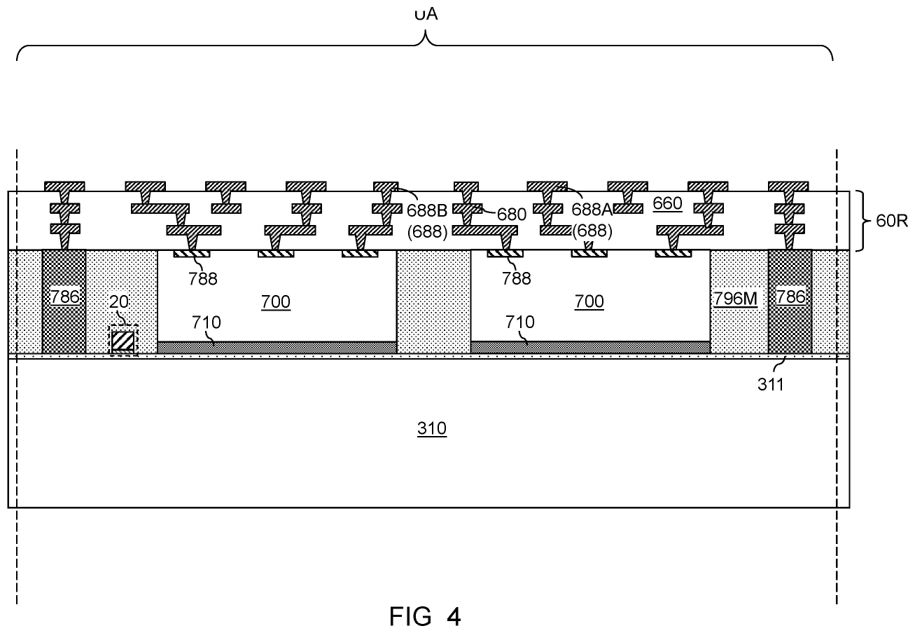

Referring to FIG. 4, a redistribution structure 60R may be formed on top of the MC matrix 796M. The redistribution structure 60R comprises redistribution dielectric layers 660, redistribution wiring interconnects 680 that are formed in the redistribution dielectric layers 660, and bonding structures 688 electrically connected to the redistribution wiring interconnects 680 and having physically exposed top surfaces. The redistribution dielectric layers 660 include a respective dielectric polymer material such as polyimide (PI), benzocyclobutene (BCB), or polybenzobisoxazole (PBO). Each redistribution dielectric layer 660 may be formed by spin coating and drying of the respective dielectric polymer material. The thickness of each redistribution dielectric layer 660 may be in a range from 2 microns to 40 microns, such as from 4 microns to 20 microns. Each redistribution dielectric layer 660 may be patterned, for example, by applying and patterning a respective photoresist layer thereabove, and by transferring the pattern in the photoresist layer into the redistribution dielectric layer 660 using an etch process such as an anisotropic etch process. The photoresist layer may be subsequently removed, for example, by ashing.

Each of the redistribution wiring interconnects 680 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 60 nm to 300 nm, and the copper seed layer may have a thickness in a range from 100 nm to 600 nm. The metallic fill material for the redistribution wiring interconnects 680 may include copper, nickel, or copper and nickel. The thickness of the metallic fill material that is deposited for each redistribution wiring interconnect 680 may be in a range from 2 microns to 40 microns, such as from 4 microns to 10 microns, although lesser or greater thicknesses may also be used. The total number of levels of wiring in the redistribution structure 60R (i.e., the levels of the redistribution wiring interconnects 680) may be in a range from 1 to 10.

The bonding structures 688 may comprise first-type bonding structures 688A that may be used to attach solder material portions (such as solder balls), and second-type bonding structures 688B that may be used to subsequently attach local interconnect dies. In one embodiment, the first-type bonding structures 688A may comprise C4 bonding pads, and the second-type bonding structures 688B may comprise microbump structures. The bonding structures 688 may have horizontal cross-sectional shapes of rectangles, rounded rectangles, or circles. Other horizontal cross-sectional shapes may be within the contemplated scope of disclosure.

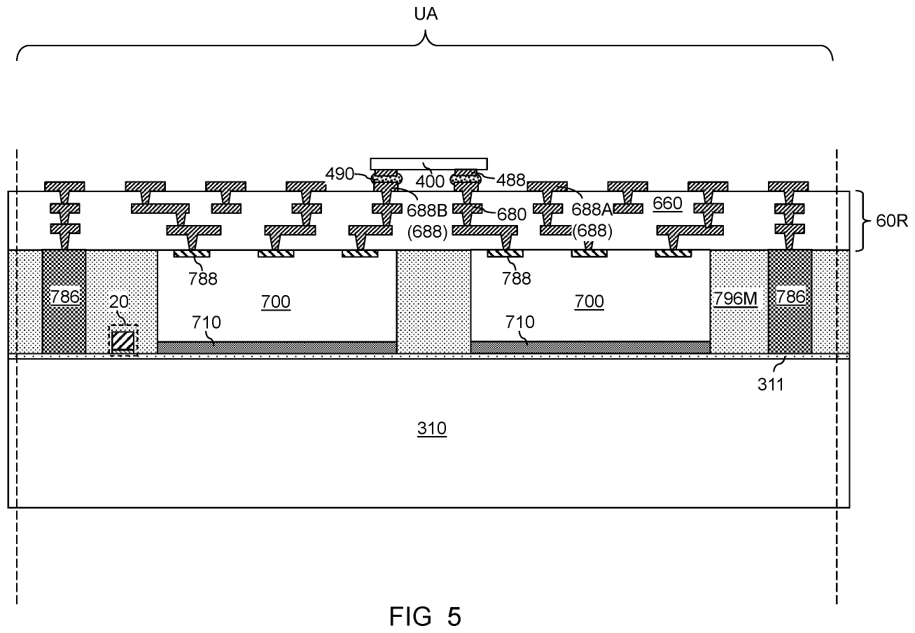

Referring to FIG. 5, a local interconnect die 400 may be attached to the second-type bonding structures 688B using solder material portions 490 within each unit area UA. The local interconnect die 400 may comprise, for example, a local silicon interconnect (LSI) die including a silicon substrate and metal interconnect structures embedded within inorganic dielectric material layers. The local interconnect die 400 may provide electrical paths for signal transmission between semiconductor dies 700 within a same unit area UA. In one embodiment, the local interconnect die 400 may comprise an array of bump structures 488, which is bonded to the second-type bonding structures 688B through an array of solder material portions 490.

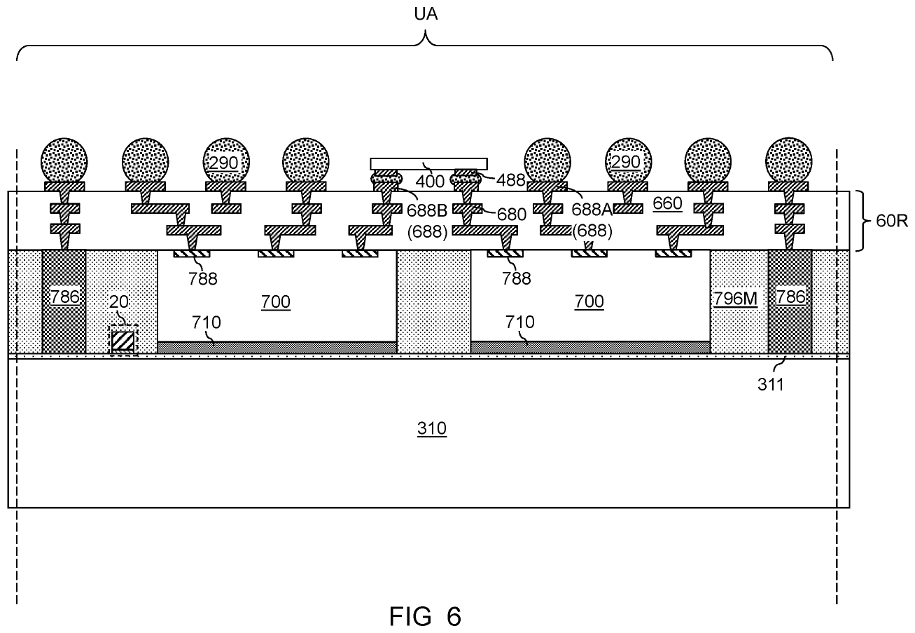

Referring to FIG. 6, additional solder material portions 290 may be attached to the first-type bonding structures 688A of the redistribution structure 60R. The additional solder material potions 290 may comprise solder balls having a greater height than the combination of a local interconnect die 400, an array of bump structures 488, and an array of solder material portions 490. For example, the additional solder material portions 290 may have a diameter in a range from 30 microns to 100 microns, such as from 40 microns to 70 microns, although lesser and greater diameters may also be used.

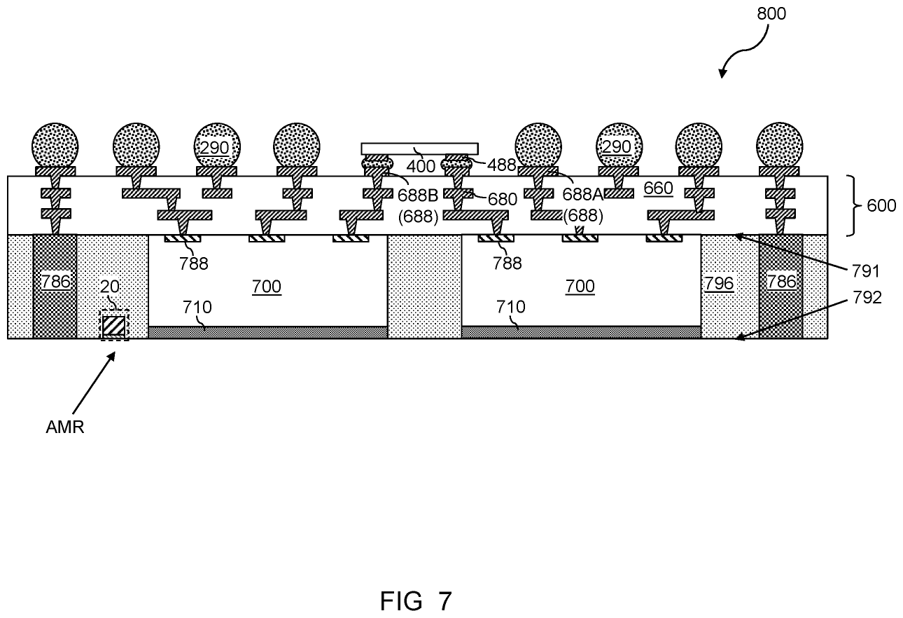

Referring to FIG. 7, an ultraviolet radiation may be irradiated through the carrier wafer 310 onto the LTHC layer 311. Upon irradiation with the ultraviolet radiation, the LTHC layer 311 generates heat, and is decomposed. The carrier wafer 310 may be detached from the reconstituted wafer including a two-dimensional array of assemblies of at least one semiconductor die 700, a set of at least one alignment mark structure 20, a molding compound die frame, and an organic interposer which is a portion of the redistribution structure 60R located within a respective unit area UA, an optional local interconnect die 400, and an array of solder material portions 290. A suitable clean process may be performed to remove residual material portions from the decomposed LTHC layer 311. Generally, the carrier wafer 310 is detached from an assembly comprising a molding compound matrix 796M, semiconductor dies 700, and alignment mark structures 20. The reconstituted wafer is diced along dicing channels, which may coincide with boundaries between neighboring pairs of unit areas. Each diced portion of the reconstituted wafer comprises a fan-out package 800.

A plurality of fan-out packages 800 may be formed by dicing the molding compound matrix 796M. Each fan-out package 800 comprises at least one semiconductor die 700, a set of at least one alignment mark structure 20, and a molding compound die frame 796 that is a cut portion of the molding compound matrix 796M.

Generally, embodiments of the present disclosure provide a device structure comprising a fan-out package 800. The fan-out package 800 comprises: a molding compound die frame 796 laterally surrounding at least one semiconductor die 700; and an organic interposer 600 comprising redistribution dielectric layers 660 embedding redistribution wiring interconnects 680 and located on a first horizontal surface 791 of the molding compound die frame 796. An alignment mark region AMR including a localized recess region is located within an opening in a second horizontal surface 792 of the molding compound die frame 796. The lateral extent of each alignment mark region AMR may be defined by the lateral extent of the localized recess region, which is defined by sidewalls and a recess surface of the molding compound die frame 796 that laterally surrounds, and contacts, an alignment mark structure 20. The localized recess region extends from the second horizontal surface 792 toward the organic interposer 600.

In one embodiment, the alignment mark region AMR does not have any areal overlap with the at least one semiconductor die 700 in a plan view along a direction that is perpendicular to the first horizontal surface 791. As used herein, a plan view refers to a view along a vertical direction such as a direction that is perpendicular to the first horizontal surface 791. In one embodiment, each alignment mark structure 20 may be located within a respective localized recess region. In one embodiment, each alignment mark structure 20 may have a same volume as a respective localized recess region. In this embodiment, a physically exposed planar surface of an alignment mark structure 20 may be located within a horizontal plane including the second horizontal surface 792 of the molding compound die frame 796.

In one embodiment, each alignment mark structure 20 may comprise a layer stack of a plurality of metallic material layers (21, 23) including at least one horizontal interface thereamongst. In one embodiment, each alignment mark structure 20 may have a variable horizontal cross-sectional area that increases with a vertical distance from a horizontal plane including the first horizontal surface 791. In one embodiment, each alignment mark structure 20 may have a thickness that is less than the thickness of the molding compound die frame 796, and is less than the thicknesses of the at least one semiconductor die 700 and the TIV structures 786.

In one embodiment, the alignment mark structure 20 comprises a horizontal surface (such as a horizontal top surface when viewed upside down) located entirely within a horizontal plane including the second horizontal surface 792 of the molding compound die frame 796. In one embodiment, the alignment mark structure 20 comprises sidewalls and a bottom surface (when viewed upside down) that are in direct contact with the molding compound die frame 796.

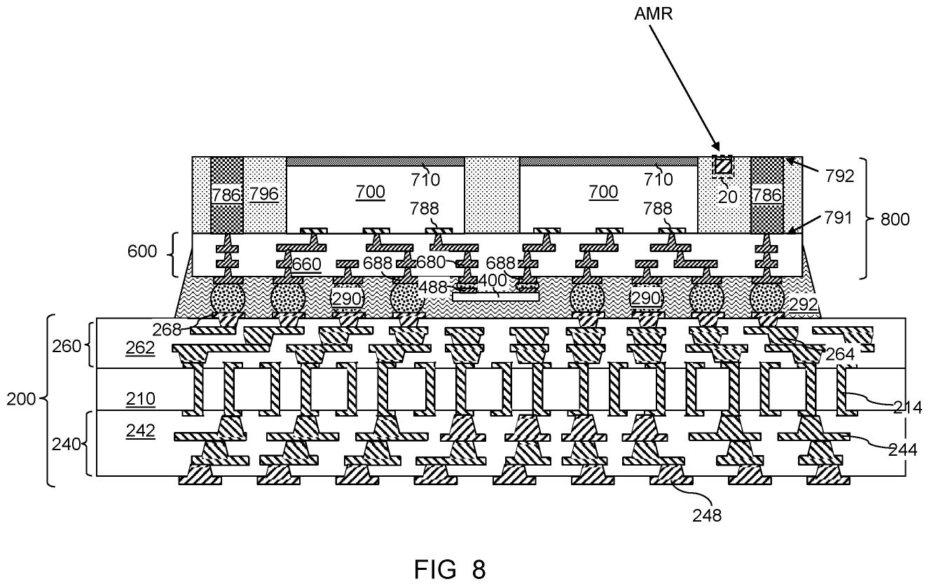

Referring to FIG. 8, a packaging substrate 200 may be bonded to the fan-out package 800. The packaging substrate 200 may be a cored packaging substrate including a core substrate 210, or a coreless packaging substrate that does not include a package core. Alternatively, the packaging substrate 200 may include a system-on-integrated packaging substrate (SoIS) including redistribution layers. dielectric interlayers, and/or at least one embedded interposer (such as a silicon interposer). Such a system-integrated packaging substrate may include layer-to-layer interconnections using solder material portions, microbumps, underfill material portions (such as molded underfill material portions), and/or an adhesion film. While the present disclosure is described using a cored packaging substrate, it is understood that the scope of the present disclosure is not limited by any particular type of substrate package. For example, an SoIS may be used in lieu of a cored packaging substrate. In embodiments in which SoIS is used, the core substrate 210 may include a glass epoxy plate including an array of through-plate holes. An array of through-core via structures 214 including a metallic material may be provided in the through-plate holes. Each through-core via structure 214 may, or may not, include a cylindrical hollow therein. Optionally, dielectric liners (not illustrated) may be used to electrically isolate the through-core via structures 214 from the core substrate 210.

The packaging substrate 200 may include board-side surface laminar circuit (SLC) 240 and a chip-side surface laminar circuit (SLC) 260. The board-side SLC may include board-side insulating layers 242 embedding board-side wiring interconnects 244. The chip-side SLC 260 may include chip-side insulating layers 262 embedding chip-side wiring interconnects 264. The board-side insulating layers 242 and the chip-side insulating layers 262 may include a photosensitive epoxy material that may be lithographically patterned and subsequently cured. The board-side wiring interconnects 244 and the chip-side wiring interconnects 264 may include copper that may be deposited by electroplating within patterns in the board-side insulating layers 242 or the chip-side insulating layers 262.

In one embodiment, the chip-side surface laminar circuit 260 comprises chip-side wiring interconnects 264 that are connected to an array of substrate bonding pads 268. The array of substrate bonding pads 268 may be configured to allow bonding through C4 solder balls. The board-side surface laminar circuit 240 comprises board-side wiring interconnects 244 that are connected to an array of board-side bonding pads 248. The array of board-side bonding pads 248 is configured to allow bonding through solder joints having a greater dimension than the C4 solder balls. While the present disclosure is described using an embodiment in which the packaging substrate 200 includes a chip-side surface laminar circuit 260 and a board-side surface laminar circuit 240, embodiments are expressly contemplated herein in which one of the chip-side surface laminar circuit 260 and the board-side surface laminar circuit 240 is omitted, or is replaced with an array of bonding structures such as microbumps. In an illustrative example, the chip-side surface laminar circuit 260 may be replaced with an array of microbumps or any other array of bonding structures.

The fan-out package 800 may be attached to the packaging substrate 200 using the solder material portions 290, which are also referred to package-substrate-bonding (FSB) solder material portions 290. Specifically, each of the FSB solder material portions 290 may be bonded to a respective one of the substrate bonding pads 268 and to a respective one of the bonding structures 688 located on the fan-out package 800. A reflow process may be performed to reflow the FSB solder material portions 290 such that each FSB solder material portion 290 may be bonded to a respective one of the substrate bonding pads 268 and to a respective one of the bonding structures 688.

An underfill material may be applied into a gap between the fan-out package 800 and the packaging substrate 200. The underfill material may comprise any underfill material known in the art. An underfill material portion may be formed around the FSB solder material portions 290 in the gap between the fan-out package 800 and the packaging substrate 200. This underfill material portion is herein referred to as an package-substrate underfill material portion 292, or as a PS underfill material portion 292.

According to an aspect of the present disclosure, a device structure is provided, which comprises: a fan-out package 800 that comprises a molding compound die frame 796, at least one semiconductor die 700 that is laterally surrounded by the molding compound die frame 796, and an organic interposer 600 comprising redistribution dielectric layers 660 embedding redistribution wiring interconnects 680 and located on a first horizontal surface 791 of the molding compound die frame 796; and a packaging substrate 200 that is bonded to bonding structures 688 of the organic interposer 600. An alignment mark region AMR including a localized recess region is located within an opening in a second horizontal surface 792 of the molding compound die frame 796.

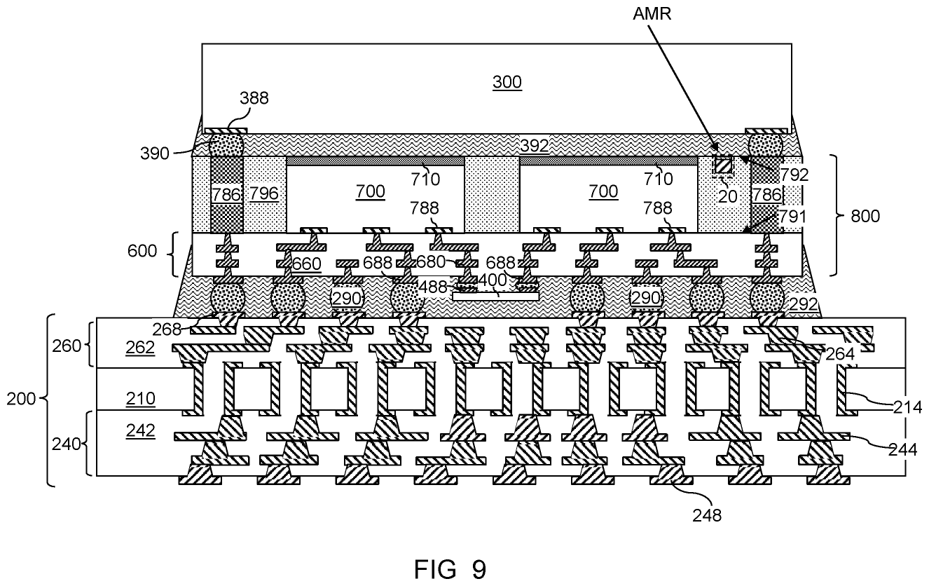

Referring to FIG. 9, an additional semiconductor die 300 may be attached to the fan-out package 800. The additional semiconductor die 300 may be any type of semiconductor die known in the art. For example, the additional semiconductor die 300 may comprise a logic de, a memory die, or a system-on-integrated-chip (SoIC) die. The additional semiconductor die 300 may comprise an array of bonding structures 388, which may comprise an array of C4 pads or an array of microbumps. Solder material portions 390 may be used to provide bonding between the array of bonding structures 388 in the additional semiconductor die 300 and the physically exposed top surfaces of the TIV structures 786. In one embodiment, the TIV structures 786 may laterally surround each semiconductor die 700 within the fan-out package 800. An underfill material portion 392 may be applied to the gap between the fan-out package 800 and the additional semiconductor die 300. A stiffener ring (not shown) or a lid structure (not shown) may be optionally attached to the fan-out package 800 or the packaging substrate 200.

In one embodiment, the additional semiconductor die 300 overlies the fan-out package 800, and is attached to the fan-out package 800. The fan-out package 800 comprises through-interposer via (TIV) structures 786 that vertically extend through the molding compound die frame 796. In one embodiment, the additional semiconductor die 300 is bonded to the TIV structures 786 through an array of solder material portions 390. In one embodiment, the alignment mark region AMR has an areal overlap with the additional semiconductor die 300 and does not have any areal overlap with the at least one semiconductor die 700.

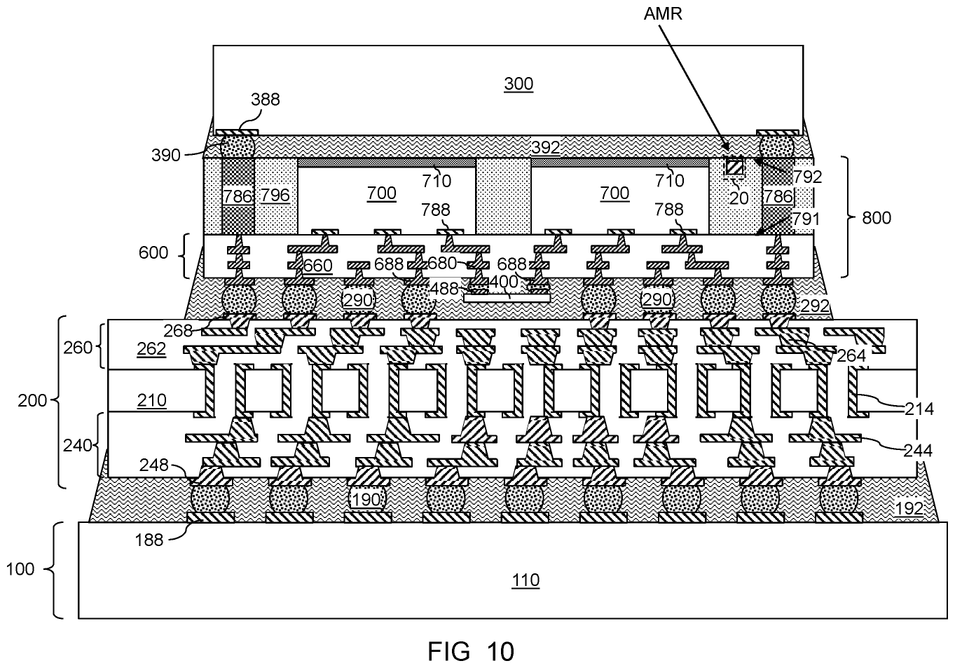

Referring to FIG. 10, a printed circuit board (PCB) 100 including a PCB substrate 110 and PCB bonding pads 188 may be provided. The PCB 100 includes a printed circuitry (not shown) at least on one side of the PCB substrate 110. An array of solder joints 190 may be formed to bond the array of board-side bonding pads 248 to the array of PCB bonding pads 188. The solder joints 190 may be formed by disposing an array of solder balls between the array of board-side bonding pads 248 and the array of PCB bonding pads 188, and by reflowing the array of solder balls. An additional underfill material portion, which is herein referred to as a board-substrate underfill material portion 192 or a BS underfill material portion 192, may be formed around the solder joints 190 by applying and shaping an underfill material. The packaging substrate 200 is attached to the PCB 100 through the array of solder joints 190.

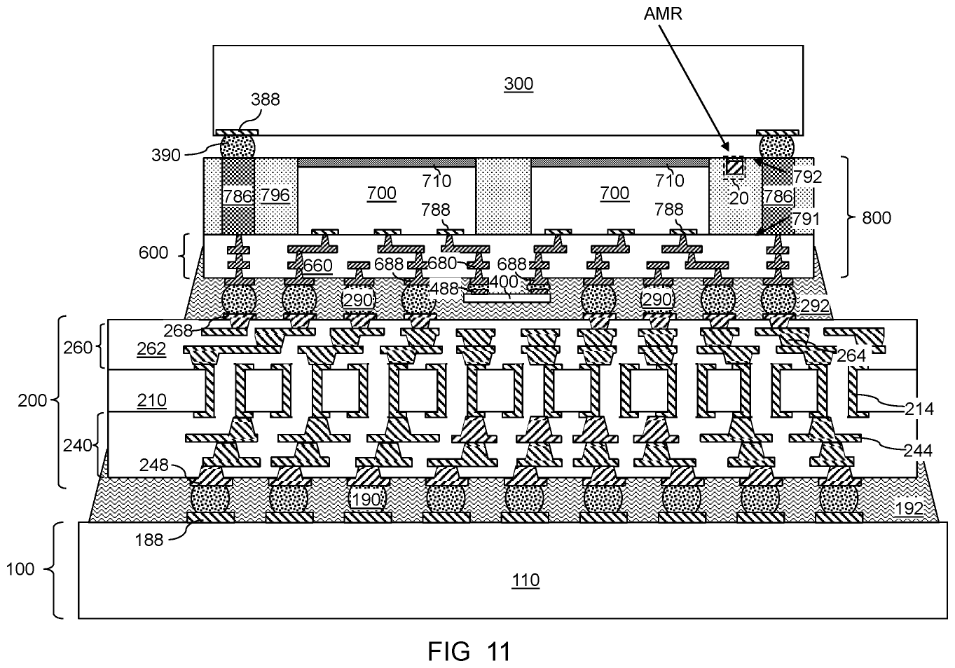

Referring to FIG. 11, a first alternative configuration of the first embodiment structure may be derived from the first embodiment structure illustrated in FIG. 10 by omitting application of an underfill material between the fan-out package 800 and the additional semiconductor die 300.

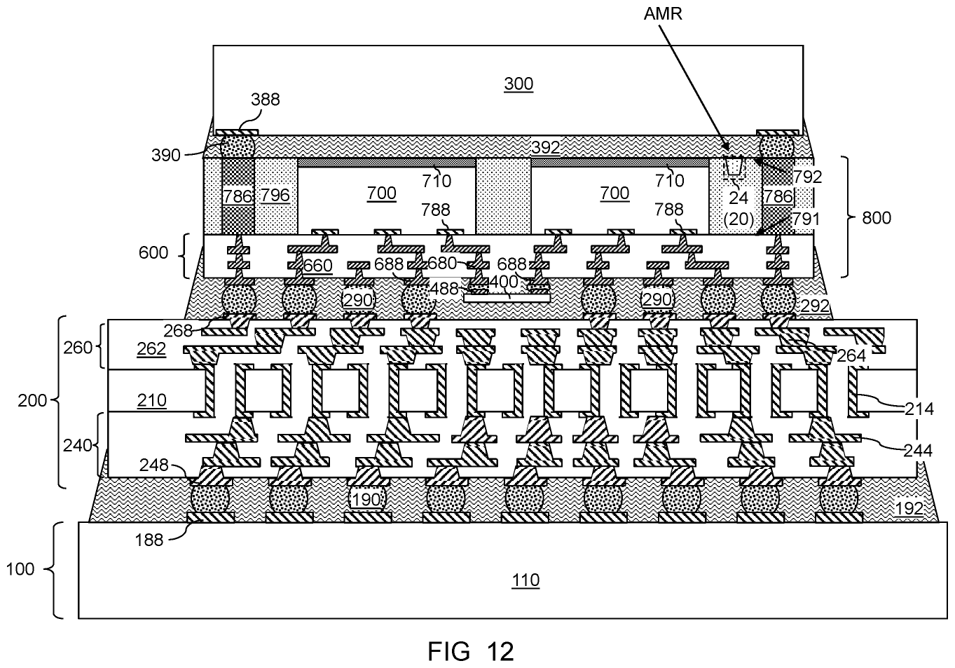

Referring to FIG. 12, a second alternative configuration of the first embodiment structure may be derived from the first embodiment structure illustrated in FIG. 10 by using a dielectric alignment mark structure 24 (as described with reference to FIG. 1E) as the alignment mark structure 20. In one embodiment, each alignment mark structure 20 comprises a dielectric material portion (referred to as dielectric alignment mark structure 24) having a variable horizontal cross-sectional area that increases with a vertical distance from a horizontal plane including the first horizontal surface 791. This geometrical feature is a distinctive structural feature that results from use of the dielectric alignment mark structure 24 in the manner described above. The variable horizontal cross-sectional area decreases with a vertical distance downward from a horizontal plane including the second horizontal surface 792.

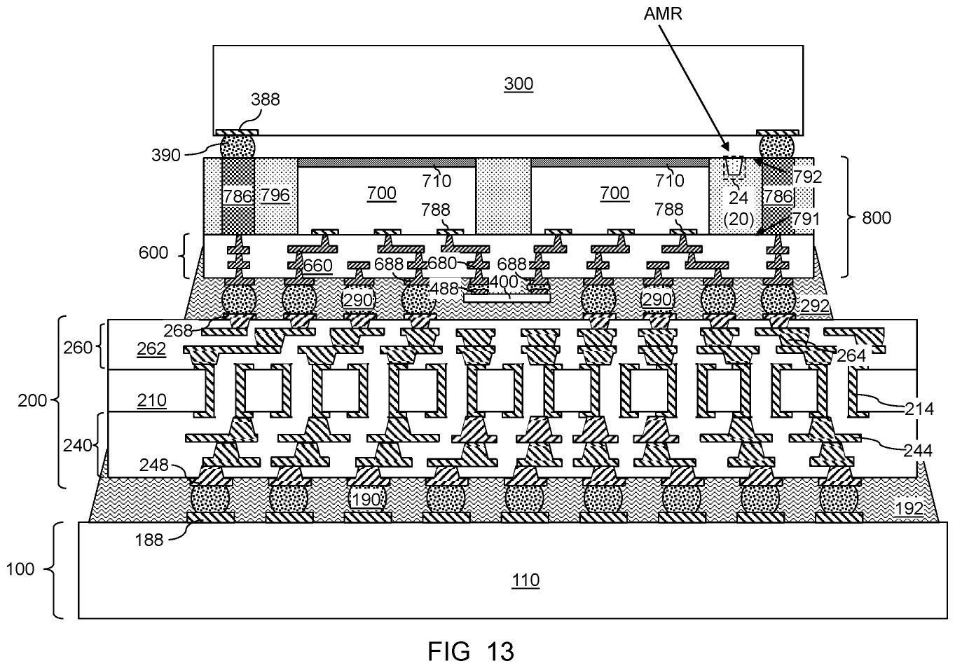

Referring to FIG. 13, a third alternative configuration of the first embodiment structure may be derived from the second alternative configuration of the first embodiment structure illustrated in FIG. 12 by omitting application of an underfill material between the fan-out package 800 and the additional semiconductor die 300.

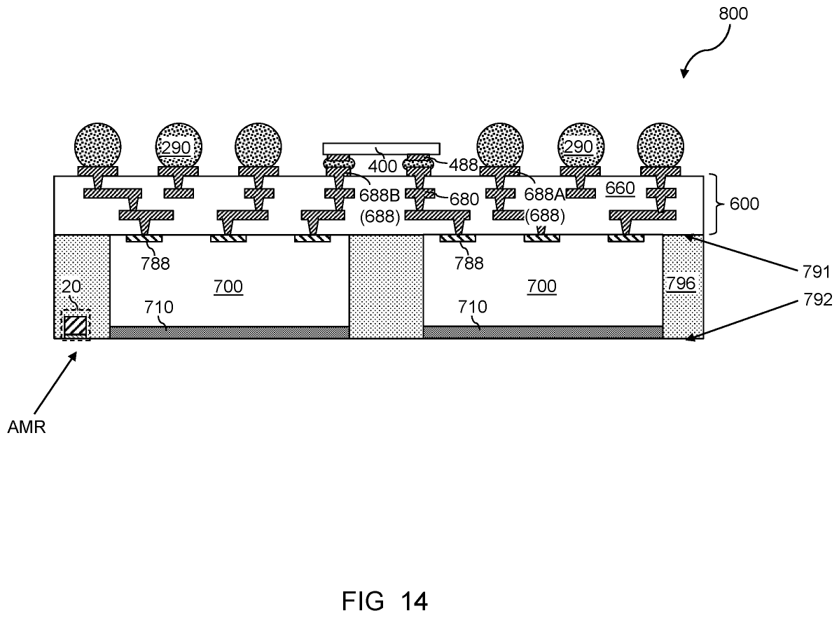

Referring to FIG. 14, a second embodiment structure comprising a fan-out package 800 is illustrated according to a second embodiment of the present disclosure. The second embodiment structure may be derived from the first embodiment structure illustrated in FIG. 7 by omitting formation of the TIV structures 786.

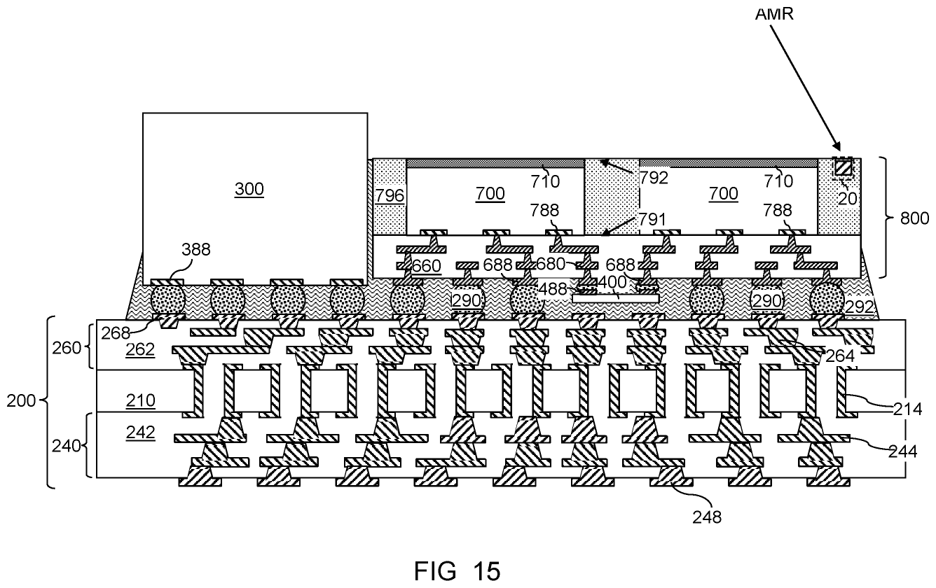

Referring to FIG. 15, the second embodiment structure is illustrated after formation of an assembly including the fan-out package 800, an optional additional semiconductor die 300, and a packaging substrate 200. Generally, the second embodiment structure may be formed by performing the processing steps described with reference to FIG. 8 with an optional modification in the locations of the bonding structures (268, 688) and the solder material portions 290. In embodiments in which the optional additional semiconductor die 300 is placed, the optional additional semiconductor die 300 may be attached to the packaging substrate 200 using additional solder material portions 290 between substrate bonding pads 268 and semiconductor bonding pads 388. A package-substrate underfill material portion 292 may be applied around the solder material portions 290. In embodiments in which the additional semiconductor die 300 is used, the top surface of the additional semiconductor die may be located at, above, or below, the horizontal plane including the top surface of the fan-out package 800.

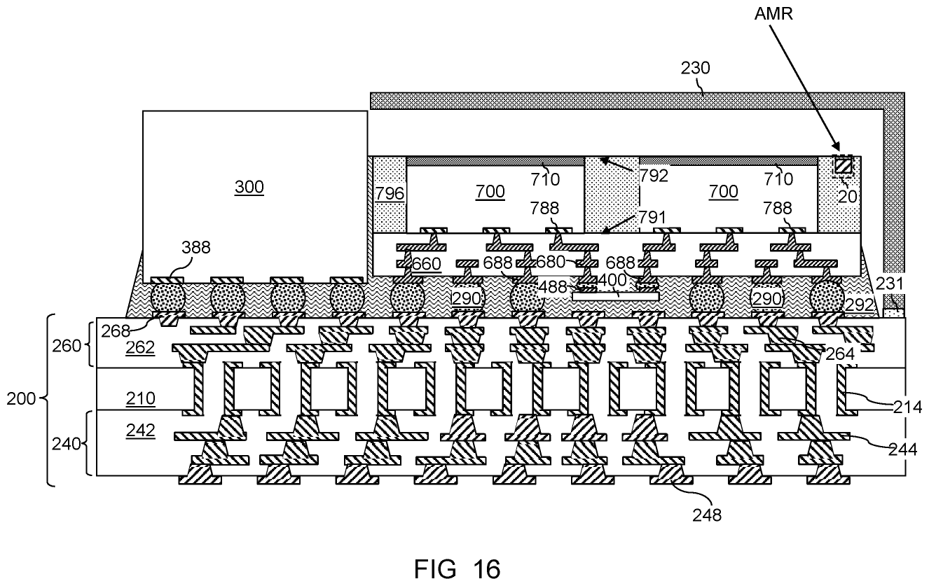

Referring to FIG. 16, a lid structure 230 may be attached to the packaging substrate 200, for example, using an adhesive layer 231. In one embodiment, the lid structure 230 comprises a sidewall and a horizontal cap portion. In one embodiment, the horizontal cap portion overlies and covers at least an entirety of the at least one semiconductor die 700 and the alignment mark region AMR. The horizontal cap portion of the lid structure 230 may, or may not, cover the additional semiconductor die 300. An alignment mark structure 20 is located within the localized recess region of the alignment mark region AMR.

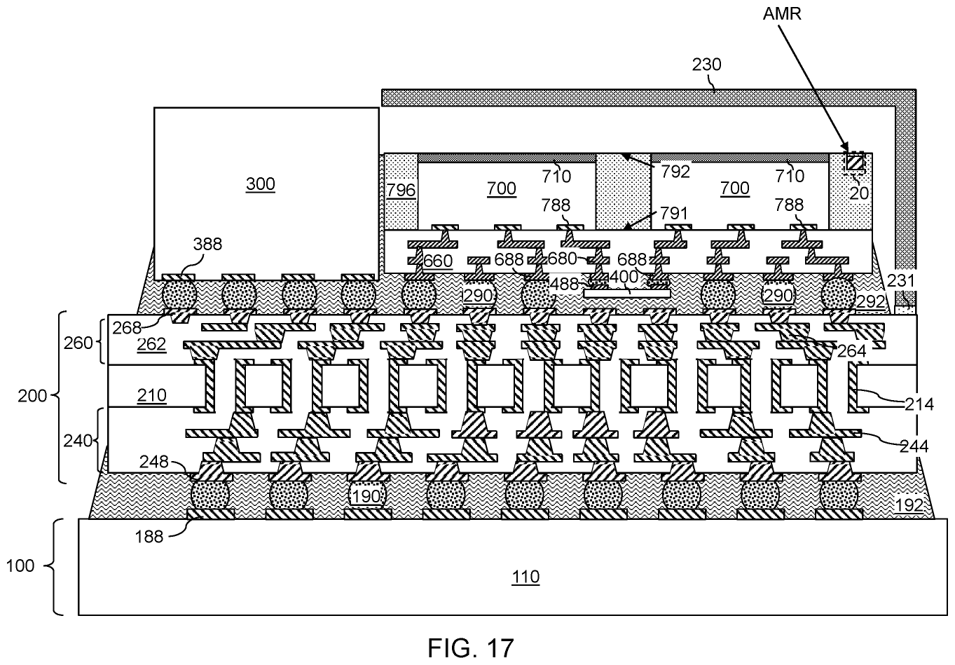

Referring to FIG. 17, the processing steps described with reference to FIG. 10 may be performed to attach an printed circuit board 100 to the assembly including the fan-out package 800, the additional semiconductor die 300, the packaging substrate 200, and the lid structure 230.

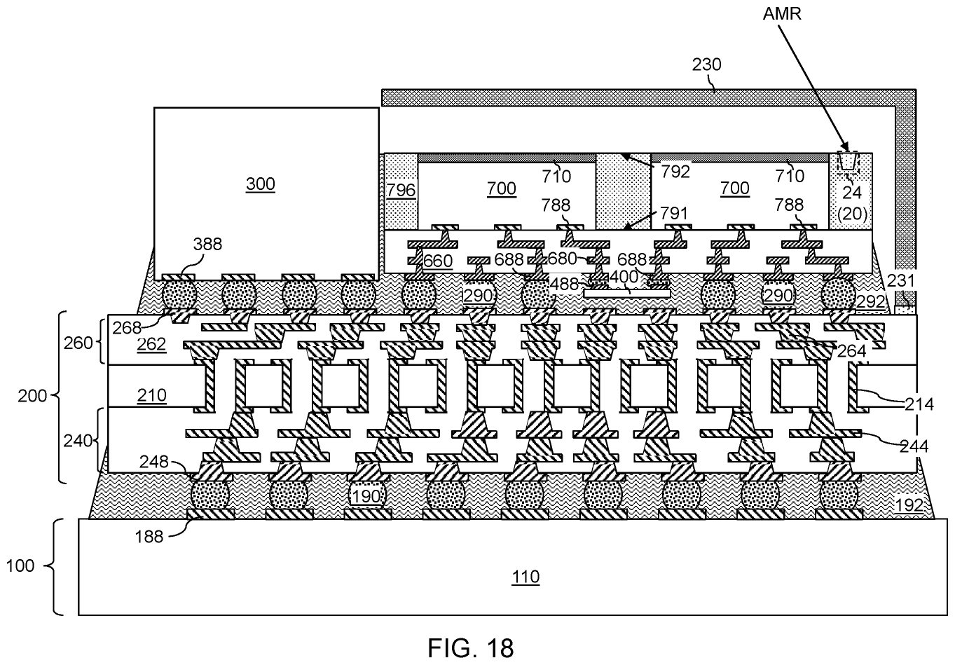

Referring to FIG. 18, an alternative configuration of the second embodiment structure may be derived from the first embodiment structure illustrated in FIG. 17 by using a dielectric alignment mark structure 24 (as described with reference to FIG. 1E) as the alignment mark structure 20. In one embodiment, each alignment mark structure 20 comprises a dielectric material portion 24 having a variable horizontal cross-sectional area that increases with a vertical distance from a horizontal plane including the first horizontal surface 791. The variable horizontal cross-sectional area decreases with a vertical distance downward from a horizontal plane including the second horizontal surface 792.

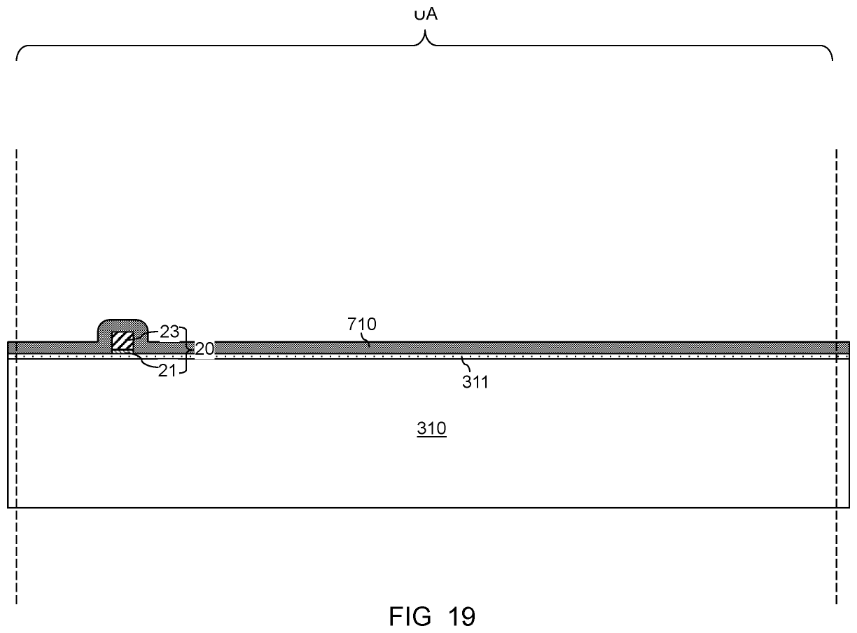

Referring to FIG. 19, a third embodiment structure according to a third embodiment of the present disclosure may be derived from the first embodiment structure illustrated in FIGS. 1A-1E by forming a die attachment film 710 over the entire area of the carrier wafer 310 and over each of the alignment mark structures 20. In this embodiment, the die attachment film 710 may have the same area as the carrier wafer 310, and may be free of any opening therethrough. Generally, the die attachment film 710 may be conformally formed over the alignment mark structures 20 and above the carrier wafer 310.

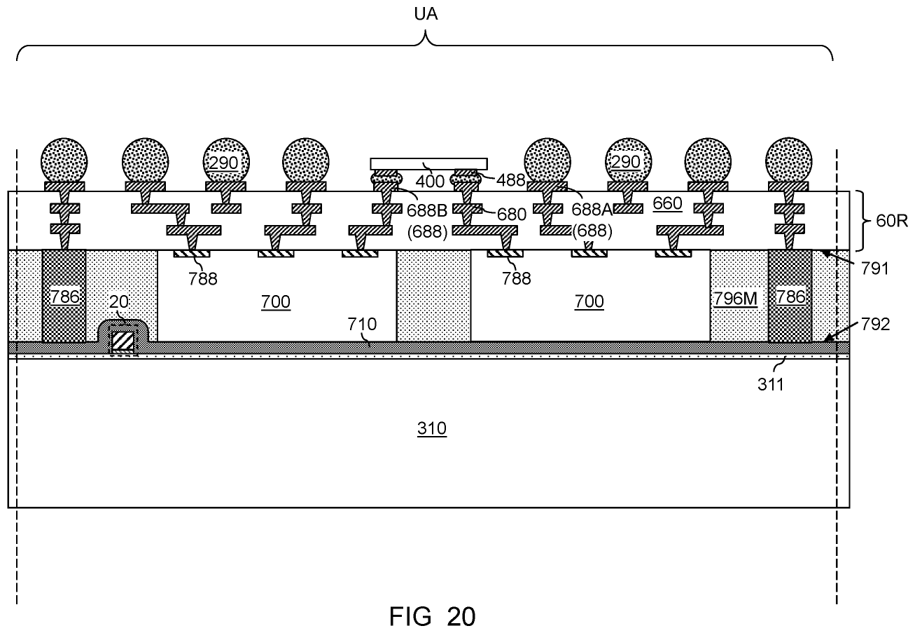

Referring to FIG. 20, the processing steps described with reference to FIGS. 2-6 may be performed with a modification that the semiconductor dies 700 without a die attachment film thereupon. In other words, the die attachment film 710 is provided on the top surface of the carrier wafer 310 instead of surfaces of the semiconductor dies 700 prior to performing the pick-and-place operations. Thus, each semiconductor die 700 is disposed over the die attachment film 710.

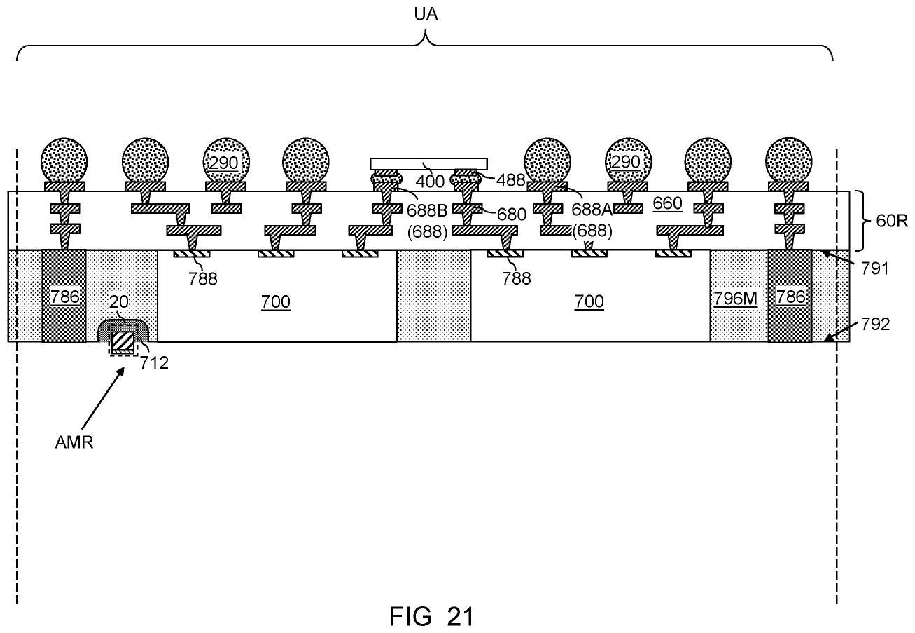

Referring to FIG. 21, an ultraviolet radiation may be irradiated through the carrier wafer 310 onto the LTHC layer 311. Upon irradiation with the ultraviolet radiation, the LTHC layer 311 generates heat, and is decomposed. The carrier wafer 310 may be detached from the reconstituted wafer including a two-dimensional array of assemblies of at least one semiconductor die 700, a set of at least one alignment mark structure 20, a die attachment film 710, a molding compound die frame, and an organic interposer which is a portion of the redistribution structure 60R located within a respective unit area UA, an optional local interconnect die 400, and an array of solder material portions 290. A suitable clean process may be performed to remove residual material portions from the decomposed LTHC layer 311. Generally, the carrier wafer 310 is detached from an assembly comprising a molding compound matrix 796M, semiconductor dies 700, and alignment mark structures 20.

Subsequently, an isotropic etch process may be performed to remove the horizontally-extending portion of the die attachment film 710 from underneath the horizontal plane including the second horizontal surface 792 of each molding compound die frame, which is a portion of the molding compound matrix 796M. For example, a wet etch process using an organic solvent may be used to remove the horizontally-extending portion of the die attachment film 710. Each remaining portion of the die attachment film 710 located within a respective alignment mark region AMR is herein referred to as a die attachment film 712, which has the same material composition and the same thickness as the die attachment film 710 illustrated in FIG. 19. In one embodiment, each die attachment film 712 may laterally surround a respective alignment mark structure 20.

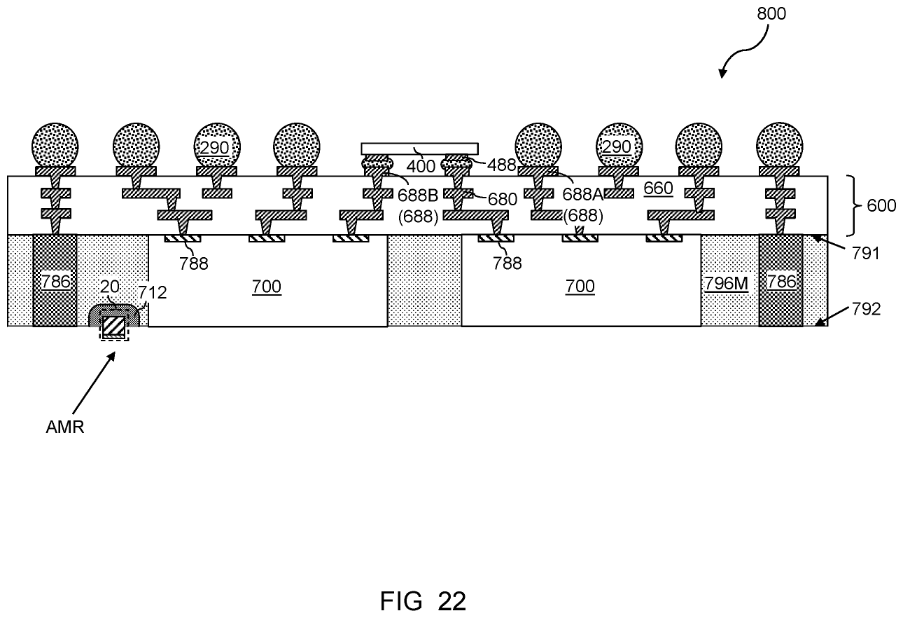

Referring to FIG. 22, the reconstituted wafer is diced along dicing channels, which may coincide with boundaries between neighboring pairs of unit areas. Each diced portion of the reconstituted wafer comprises a fan-out package 800. A plurality of fan-out packages 800 may be formed by dicing the molding compound matrix 796M. Each fan-out package 800 comprises at least one semiconductor die 700, a set of at least one alignment mark structure 20, and a molding compound die frame 796 that is a cut portion of the molding compound matrix 796M.

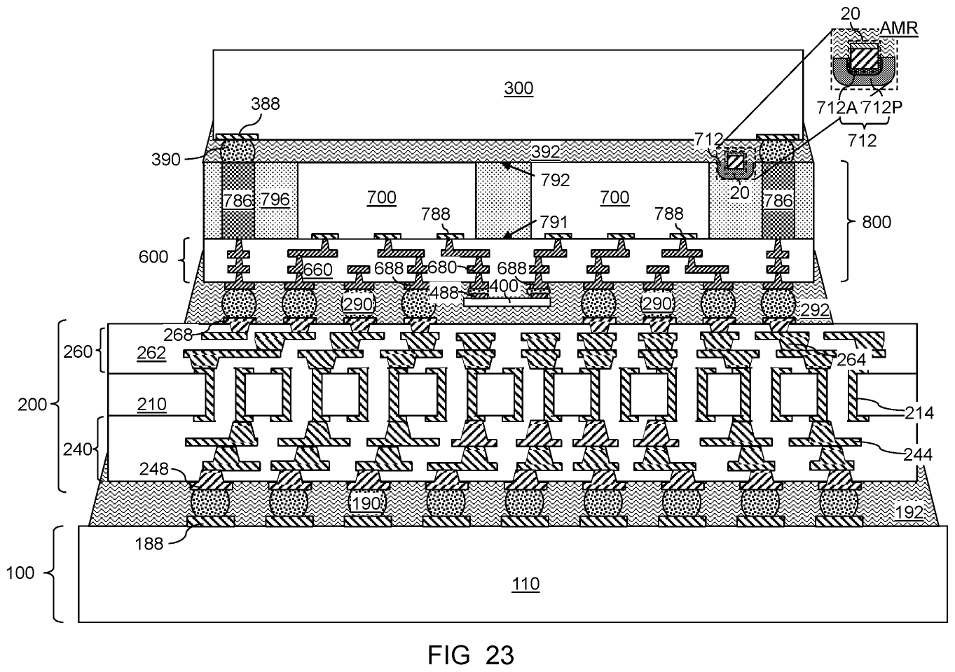

Referring to FIG. 23, the processing steps described with reference to FIGS. 8-10 may be performed to attach the fan-out package 800 to a packaging substrate 200, to attach an additional semiconductor die 300 to the packaging substrate 200, and to attach an assembly of the fan-out package 800, the packaging substrate 200, and the additional semiconductor die 300 to a printed circuit board 100.

The fan-out package 800 comprises: a molding compound die frame 796 laterally surrounding at least one semiconductor die 700; and an organic interposer 600 comprising redistribution dielectric layers 660 embedding redistribution wiring interconnects 680 and located on a first horizontal surface 791 of the molding compound die frame 796. An alignment mark region AMR including a localized recess region is located within an opening in a second horizontal surface 792 of the molding compound die frame 796. The lateral extent of each alignment mark region AMR may be defined by the lateral extent of the localized recess region, which is defined by sidewalls and a recess surface of the molding compound die frame 796 that laterally surrounds, and contacts, an alignment mark structure 20. The localized recess region extends from the second horizontal surface 792 toward the organic interposer 600.

In one embodiment, the alignment mark region AMR does not have any areal overlap with the at least one semiconductor die 700 in a plan view along a direction that is perpendicular to the first horizontal surface 791. In one embodiment, each alignment mark structure 20 may be located within a respective localized recess region. In one embodiment, each alignment mark structure 20 may have a lesser volume than a respective localized recess region. In one embodiment, a physically exposed planar surface (such as a top surface) of an alignment mark structure 20 may be located within a horizontal plane including the second horizontal surface 792 of the molding compound die frame 796.

In one embodiment, each alignment mark structure 20 may comprise a layer stack of a plurality of metallic material layers (21, 23) including at least one horizontal interface thereamongst. In one embodiment, each alignment mark structure 20 may have a variable horizontal cross-sectional area that increases with a vertical distance from a horizontal plane including the first horizontal surface 791. In one embodiment, each alignment mark structure 20 may have a thickness that is less than the thickness of the molding compound die frame 796, and is less than the thicknesses of the at least one semiconductor die 700 and the TIV structures 786.

In one embodiment, the alignment mark structure 20 comprises a horizontal surface (such as a horizontal top surface when viewed upside down) located entirely within a horizontal plane including the second horizontal surface 792 of the molding compound die frame 796. In one embodiment, the alignment mark structure 20 is spaced from the molding compound die frame 796 by a die attachment film 712 including a polymer matrix layer 712P and an adhesive layer 712A.

An underfill material portion 392 may be formed in the gap between the fan-out package 800 and the additional semiconductor die 300. A horizontal top surface and upper portions of sidewalls of each alignment mark structure 20 may be in contact with the underfill material portion 392. Lower portions of the sidewalls of each alignment mark structure 20 may be in contact with the adhesive layer 712A of the die attachment film 712.

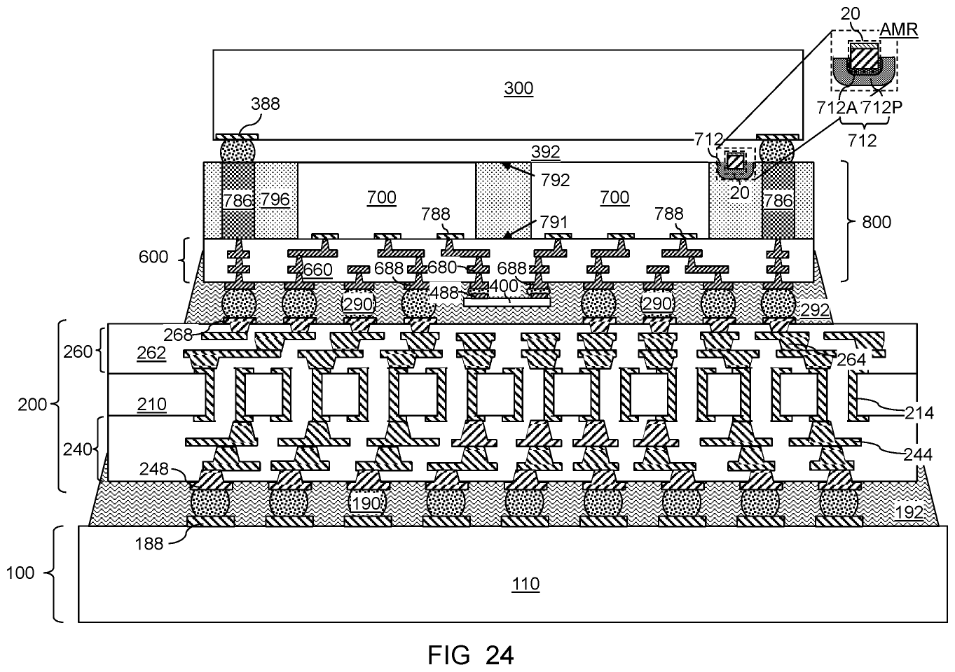

Referring to FIG. 24, a first alternative configuration of the third embodiment structure may be derived from the third embodiment structure illustrated in FIG. 23 by omitting formation of the underfill material portion 392. In this embodiment, a horizontal top surface and upper portions of sidewalls of each alignment mark structure 20 may be physically exposed, and thus, may contact a gas-phase ambient. Lower portions of the sidewalls of each alignment mark structure 20 may be in contact with the adhesive layer 712A of the die attachment film 712.

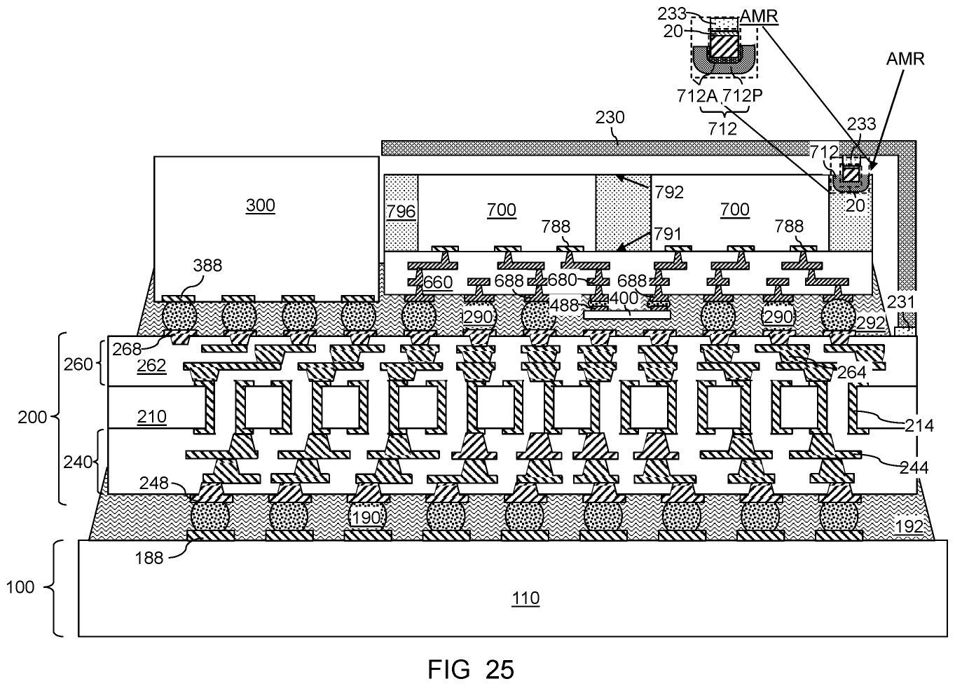

Referring to FIG. 25, a second alternative configuration of the third embodiment structure according to the third embodiment of the present disclosure by using the fan-out package 800 illustrated in FIG. 22 and by performing the processing steps described with reference to FIGS. 15-17. Optionally, a bottom surface of a horizontal cap portion of the lid structure 230 may be attached to the top surface of an alignment mark structure 20 using an additional adhesive layer 233.

In one embodiment, an alignment mark structure 20 may comprise a horizontal top surface that is located above a horizontal plane including the second horizontal surface 792 of the molding compound die frame 796. In one embodiment, the alignment mark structure 20 is spaced from the molding compound die frame 796 by a die attachment film 712 including a polymer matrix layer 712P and an adhesive layer 712A. In one embodiment, the alignment mark structure 20 is located within the localized recess region; and the horizontal cap portion of the lid structure 230 may be attached to the alignment mark structure 20 through an adhesive layer 233.

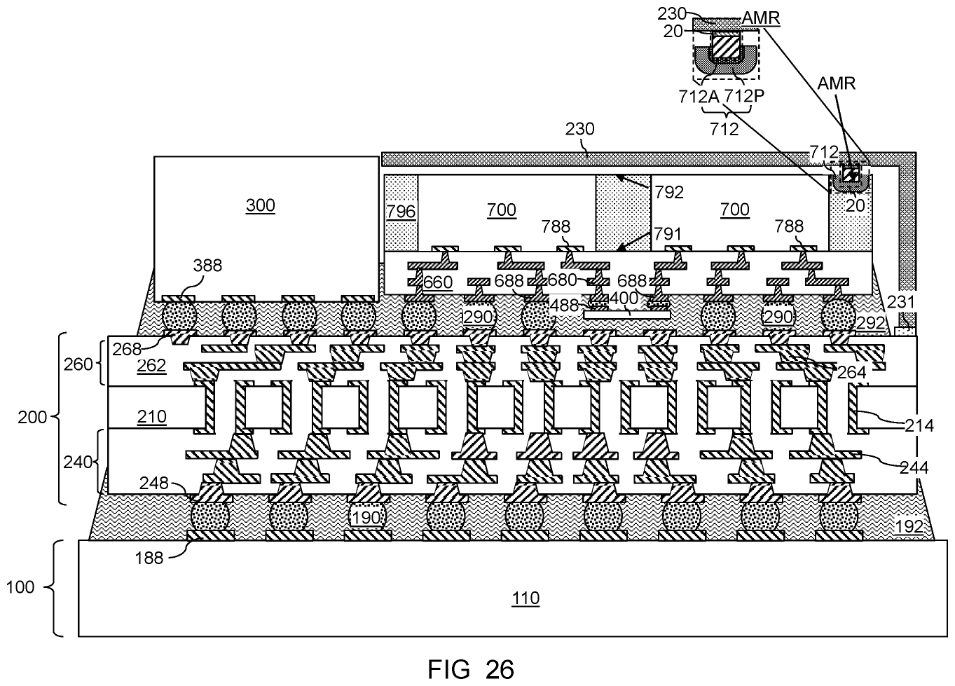

Referring to FIG. 26, a third alternative configuration of the third embodiment structure may be derived from the second alternative configuration of the third embodiment structure illustrated in FIG. 26 by not using an additional adhesive layer 233. In this embodiment, In one embodiment, the alignment mark structure 20 is located partly within the localized recess region; and the horizontal cap portion of the lid structure 230 may be in direct contact with the alignment mark structure 20.

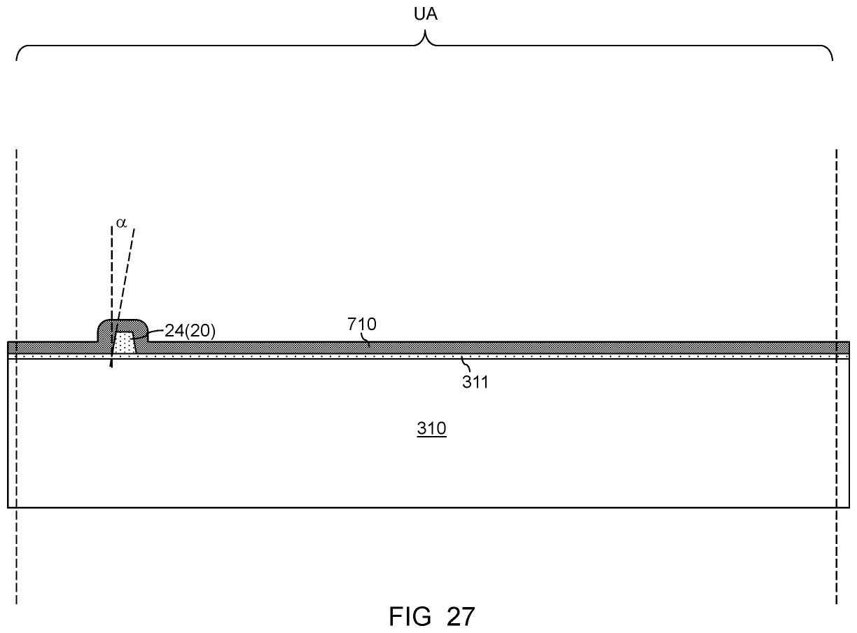

Referring to FIG. 27, a fourth embodiment structure according to a fourth embodiment of the present disclosure may be derived from the first embodiment structure illustrated in FIG. 1E by conformally attaching a die attachment film 710 directly on the physically exposed surfaces of the LTHC layer 311 and directly on the physically exposed surfaces of the dielectric alignment mark structures 24. The sidewalls of the dielectric alignment mark structures 24 may have a taper angle α with respect to a vertical direction in a range from 1 degree to 20 degrees, such as from 3 degrees to 10 degrees, although lesser and greater taper angles may also be used. In this embodiment, each of the dielectric alignment mark structures 24 may have a variable horizontal cross-sectional area that decreases with a vertical distance from the carrier wafer 310.

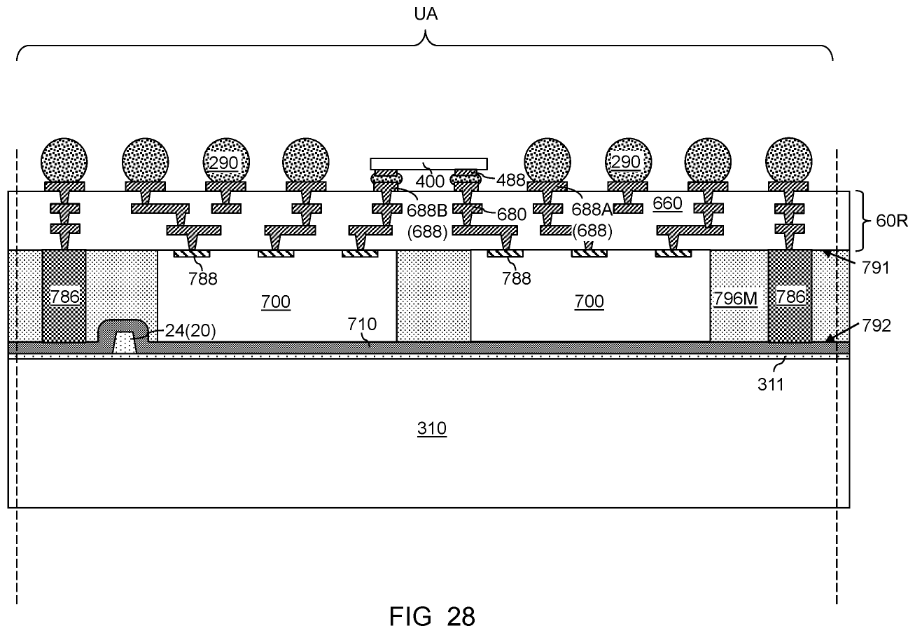

Referring to FIG. 28, the processing steps described with reference to FIGS. 2-6 may be performed with a modification that the die attachment film 710 is present as a single continuous film. In other words, the die attachment film 710 is provided on the top surface of the carrier wafer 310 instead of surfaces of the semiconductor dies 700 prior to performing the pick-and-place operations. Thus, each semiconductor die 700 is disposed over the die attachment film 710.

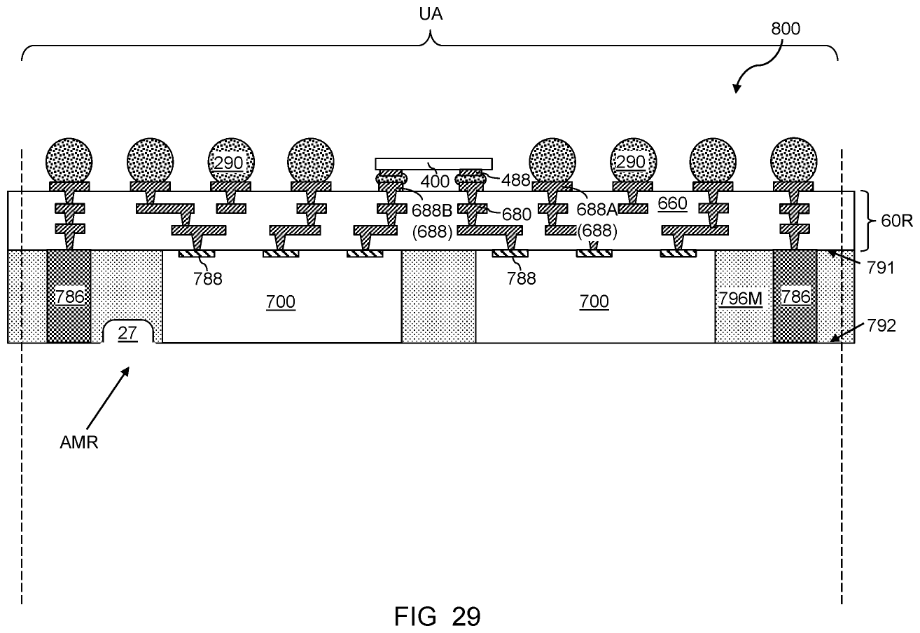

Referring to FIG. 29, an ultraviolet radiation may be irradiated through the carrier wafer 310 onto the LTHC layer 311. The carrier wafer 310 may be detached from the reconstituted wafer including a two-dimensional array of assemblies of at least one semiconductor die 700, a set of at least one alignment mark structure 20, a die attachment film 710, a molding compound die frame, and an organic interposer which is a portion of the redistribution structure 60R located within a respective unit area UA, an optional local interconnect die 400, and an array of solder material portions 290. A suitable clean process may be performed to remove residual material portions from the decomposed LTHC layer 311. Generally, the carrier wafer 310 is detached from an assembly comprising a molding compound matrix 796M, semiconductor dies 700, and alignment mark structures 20.

Subsequently, at least one isotropic etch process may be performed to remove the dielectric alignment mark structures 24 and the die attachment film 710 selective to the molding compound matrix 796M, i.e., without etching, or with minimal etching, of the molding compound matrix 796M. For example, a wet etch process using an organic solvent may be used to remove the dielectric alignment mark structures 24 and the die attachment film 710. Each alignment mark region AMR comprises a void 27 that is free of any solid phase material, and is located within a volume of a localized recess region.

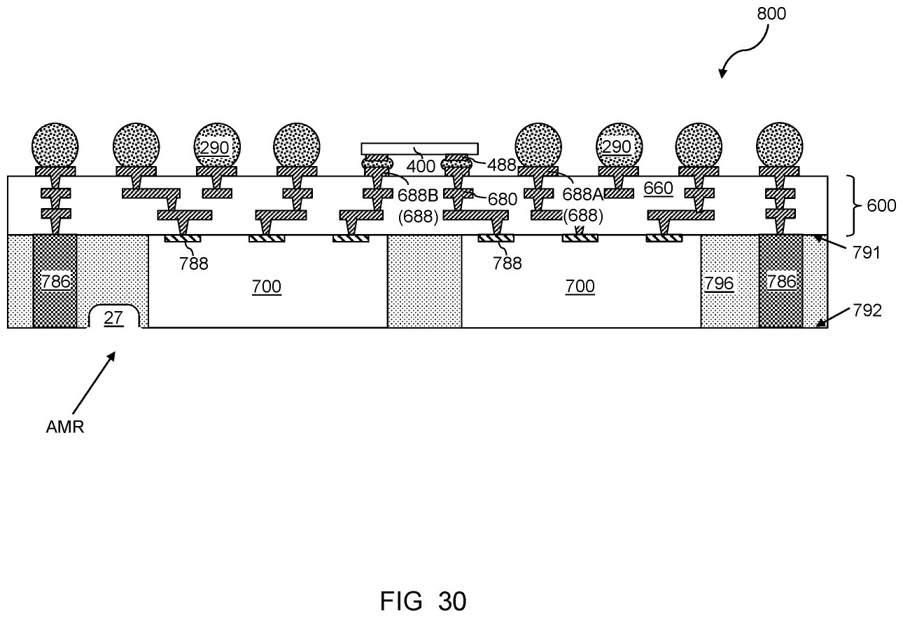

Referring to FIG. 30, the reconstituted wafer is diced along dicing channels, which may coincide with boundaries between neighboring pairs of unit areas. Each diced portion of the reconstituted wafer comprises a fan-out package 800. A plurality of fan-out packages 800 may be formed by dicing the molding compound matrix 796M. Each fan-out package 800 comprises at least one semiconductor die 700, a set of at least one alignment mark structure 20, and a molding compound die frame 796 that is a cut portion of the molding compound matrix 796M.

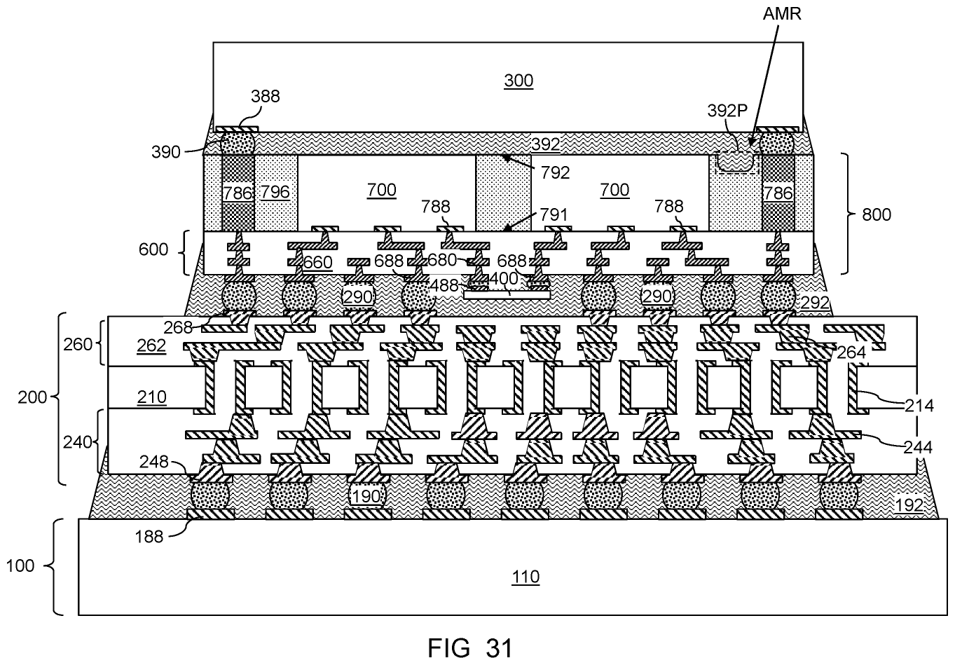

Referring to FIG. 31, the processing steps described with reference to FIGS. 8-10 may be performed to attach the fan-out package 800 to a packaging substrate 200, to attach an additional semiconductor die 300 to the packaging substrate 200, and to attach an assembly of the fan-out package 800, the packaging substrate 200, and the additional semiconductor die 300 to a printed circuit board 100.

The fan-out package 800 comprises: a molding compound die frame 796 laterally surrounding at least one semiconductor die 700; and an organic interposer 600 comprising redistribution dielectric layers 660 embedding redistribution wiring interconnects 680 and located on a first horizontal surface 791 of the molding compound die frame 796. An alignment mark region AMR including a localized recess region is located within an opening in a second horizontal surface 792 of the molding compound die frame 796.

In one embodiment, the volume of the localized recess region may be the same as a volume of an underfill material protrusion portion 392P, which is a region of the underfill material portion that fills the void 27 as formed at the processing steps of FIG. 27. The lateral extent of each alignment mark region AMR may be defined by the lateral extent of the localized recess region, which is defined by the volume of the underfill material protrusion portion 392P. The localized recess region extends from the second horizontal surface 792 toward the organic interposer 600.

In one embodiment, the alignment mark region AMR does not have any areal overlap with the at least one semiconductor die 700 in a plan view along a direction that is perpendicular to the first horizontal surface 791. In one embodiment, each underfill material protrusion portion 392P may be located within a respective localized recess region. In one embodiment, each underfill material protrusion portion 392P may have the same volume a respective localized recess region.

In one embodiment, each underfill material protrusion portion 392P may have a variable horizontal cross-sectional area that increases with a vertical distance from a horizontal plane including the first horizontal surface 791. In one embodiment, each underfill material protrusion portion 392P may have a thickness that is less than the thickness of the molding compound die frame 796, and is less than the thicknesses of the at least one semiconductor die 700 and the TIV structures 786. Each underfill material protrusion portion 392P may be in contact with sidewalls and a recessed surface the molding compound die frame 796.

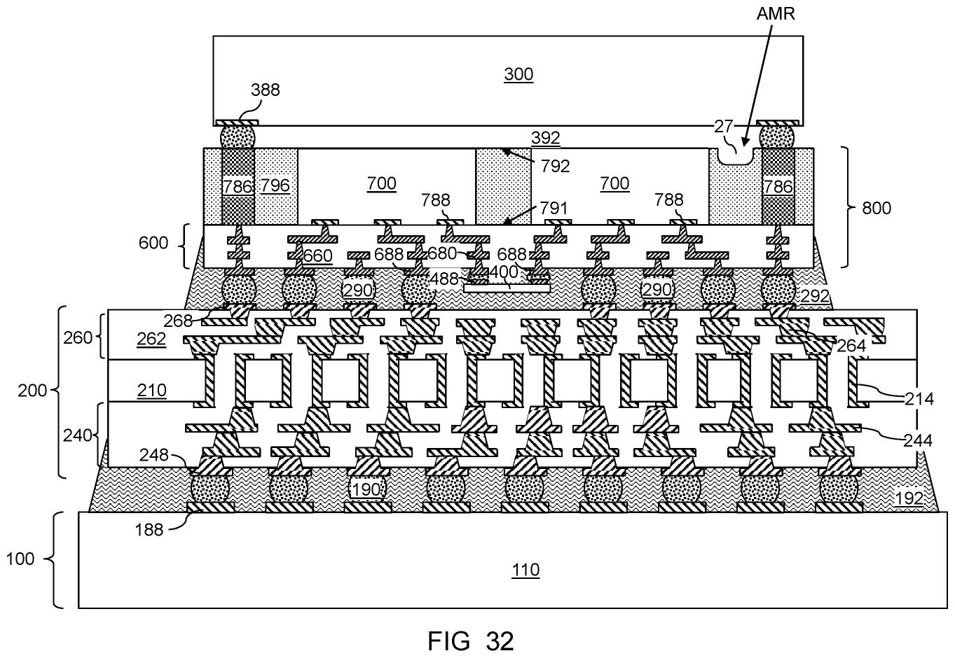

Referring to FIG. 32, a first alternative configuration of the fourth embodiment structure may be derived from the fourth embodiment structure illustrated in FIG. 29 by omitting formation of the underfill material portion 392. Each alignment mark region AMR may comprise a localized recess region defined by a respective void 27 that is free of any solid phase material. Sidewalls and a recessed surface of a molding compound die frame 796 may be physically exposed to the void 27 within each alignment mark region AMR.

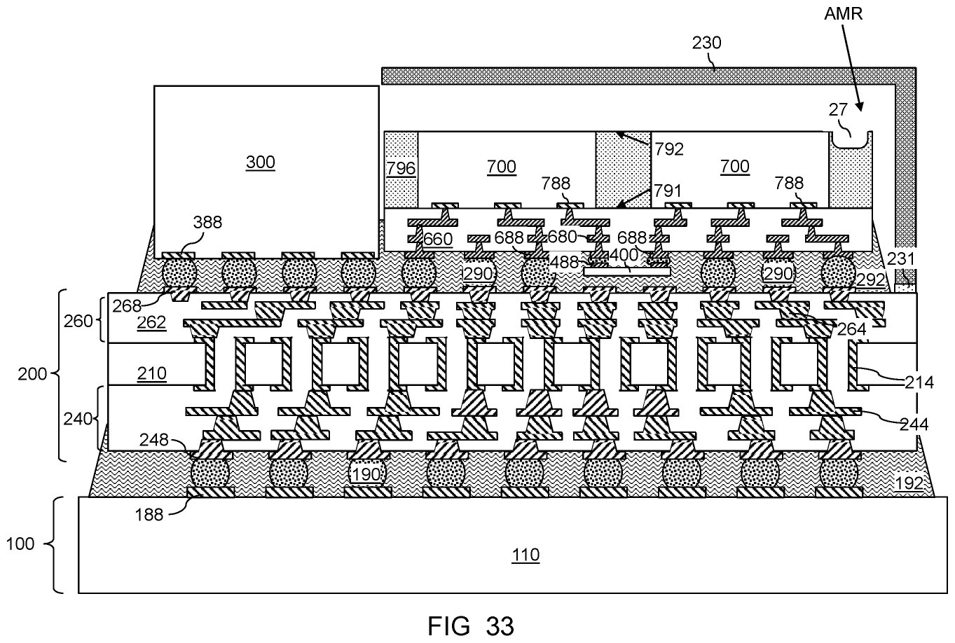

Referring to FIG. 33, a second alternative configuration of the fourth embodiment structure may be derived by using the fan-out package 800 illustrated in FIG. 28 and by performing the processing steps described with reference to FIGS. 15-17. In one embodiment, the alignment mark region AMR including a localized recess region may be comprise a void 27 that is free of any solid phase material and vertically extends from the second horizontal surface 792 of a molding compound die frame 796 toward to the first horizontal surface 791 of the molding compound die frame 796.

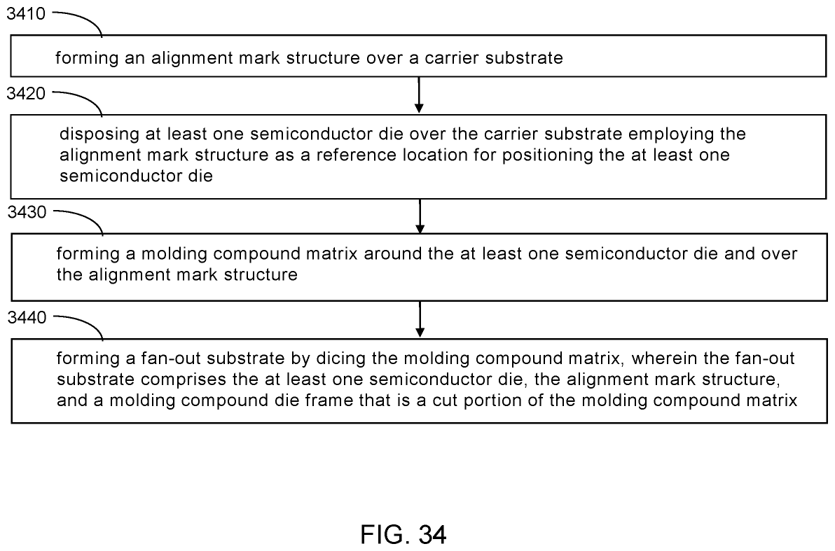

Referring to FIG. 34, a flowchart illustrates steps for forming a device structure according to an embodiment of the present disclosure.

Referring to step 3410 and FIGS. 1A-1E, 19, and 25, an alignment mark structure 20 may be formed over a carrier wafer 310.

Referring to step 3420 and FIGS. 2, 20, and 26, at least one semiconductor die 700 may be disposed (per unit area UA) over the carrier wafer 310 using the alignment mark structure 20 as a reference location for positioning the at least one semiconductor die 700.

Referring to step 3430 and FIGS. 3, 20, and 26, a molding compound matrix 796M may be formed around the at least one semiconductor die 700 and over the alignment mark structure 20.

Referring to step 3440 and FIGS. 4-18 and 20-33, a fan-out package 800 may be formed by dicing the molding compound matrix 796M. The fan-out package 800 comprises the at least one semiconductor die 700, the alignment mark structure 20, and a molding compound die frame 796 that is a cut portion of the molding compound matrix 796M.

Referring to all drawings and according to various embodiments of the present disclosure, a device structure comprising a fan-out package 800 is provided. The fan-out package 800 comprises: a molding compound die frame 796 laterally surrounding at least one semiconductor die 700; and an organic interposer 600 comprising redistribution dielectric layers 660 embedding redistribution wiring interconnects 680 and located on a first horizontal surface 791 of the molding compound die frame 796, wherein an alignment mark region AMR including a localized recess region is located within an opening in a second horizontal surface 792 of the molding compound die frame 796, and the localized recess region extends from the second horizontal surface 792 toward the organic interposer 600.

In one embodiment, the alignment mark region AMR does not have any areal overlap with the at least one semiconductor die 700 in a plan view along a direction that is perpendicular to the first horizontal surface 791. In one embodiment, an alignment mark structure 20 is located within the localized recess region.

In one embodiment, the alignment mark structure 20 comprises a layer stack of a plurality of metallic material layers (21, 23) including at least one horizontal interface thereamongst. In one embodiment, the alignment mark structure 20 comprises a dielectric material portion 24 having a variable horizontal cross-sectional area that increases with a vertical distance from a horizontal plane including the first horizontal surface 791.

In one embodiment, the alignment mark structure 20 comprises a horizontal surface located entirely within a horizontal plane including the second horizontal surface 792 of the molding compound die frame 796. In one embodiment, the alignment mark structure 20 comprises a horizontal surface that is located above a horizontal plane including the second horizontal surface 792 of the molding compound die frame 796.

In one embodiment, the alignment mark structure 20 comprises sidewalls and a bottom surface that are in direct contact with the molding compound die frame 796. In one embodiment, the alignment mark structure 20 is spaced from the molding compound die frame 796 by a die attachment film 712 including a polymer matrix layer 712P and an adhesive layer 712A.

According to an aspect of the present disclosure, a device structure is provided, which comprises: a fan-out package 800 that comprises a molding compound die frame 796, at least one semiconductor die 700 that is laterally surrounded by the molding compound die frame 796, and an organic interposer 600 comprising redistribution dielectric layers 660 embedding redistribution wiring interconnects 680 and located on a first horizontal surface 791 of the molding compound die frame 796; and a packaging substrate 200 that is bonded to bonding structures 688 of the organic interposer 600, wherein an alignment mark region AMR including a localized recess region is located within an opening in a second horizontal surface 792 of the molding compound die frame 796.

In one embodiment, the device structure comprises an additional semiconductor die 300 overlying the fan-out package 800 and attached to the fan-out package 800. In one embodiment, the fan-out package 800 comprises through-interposer via (TIV) structures 786 that vertically extend through the molding compound die frame 796; and the additional semiconductor die 300 is bonded to the TIV structures 786 through an array of solder material portions 390.

In one embodiment, the alignment mark region AMR has an areal overlap with the additional semiconductor die 300 and does not have any areal overlap with the at least one semiconductor die 700. In one embodiment, the device structure comprises a lid structure 230 that is attached to the packaging substrate 200 and comprising a horizontal cap portion that overlies and covers an entirety of the at least one semiconductor die 700 and the alignment mark region AMR. In one embodiment, an alignment mark structure 20 is located within the localized recess region; and the horizontal cap portion is in direct contact with the alignment mark structure 20 or is attached to the alignment mark structure 20 through an adhesive layer 233.

The various embodiments of the present disclosure may be used to increase the positional accuracy and the speed of pick-and-placement operations for disposing semiconductor dies 700 and TIV structures 786 over a carrier wafer 310. Each semiconductor die 700 and each TIV structure 786 may be disposed within a unit area UA using at least one alignment mark structure 20 that is located within the same unit area UA. Thus, the lateral displacement between each semiconductor die 700 and a reference point (i.e., a most proximal one of the at least one alignment mark structure 20) is less than the maximum lateral dimension of a unit area UA (such as the diagonal of a rectangular unit area UA). Likewise, the lateral displacement between each TIV structure 786 and a reference point (i.e., a most proximal one of the at least one alignment mark structure 20) is less than the maximum lateral dimension of the unit area UA. Reduction of the lateral displacement between reference points and elements that are placed during the pick-and-placement operation may be achieved through use of the alignment mark structures 20 of the present disclosure, and may increase the throughput and the process yield of the pick-and-placement operation.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device structure comprising a fan-out package, wherein the fan-out package comprises:
a molding compound die frame laterally surrounding at least one semiconductor die; and
an organic interposer comprising redistribution dielectric layers embedding redistribution wiring interconnects and located on a first horizontal surface of the molding compound die frame,
wherein an alignment mark region including a localized recess region is located within an opening in a second horizontal surface of the molding compound die frame.

2. The device structure of claim 1, wherein the alignment mark region does not have any areal overlap with the at least one semiconductor die in a plan view along a direction that is perpendicular to the first horizontal surface.

3. The device structure of claim 1, wherein an alignment mark structure is located within the localized recess region.

4. The device structure of claim 3, wherein the alignment mark structure comprises a layer stack of a plurality of metallic material layers including at least one horizontal interface thereamongst.

5. The device structure of claim 3, wherein the alignment mark structure comprises a dielectric material portion having a variable horizontal cross-sectional area that increases with a vertical distance from a horizontal plane including the first horizontal surface.

6. The device structure of claim 3, wherein the alignment mark structure comprises a horizontal surface located entirely within a horizontal plane including the second horizontal surface of the molding compound die frame.

7. The device structure of claim 3, wherein the alignment mark structure comprises a horizontal surface that is located above a horizontal plane including the second horizontal surface of the molding compound die frame.

8. The device structure of claim 3, wherein the alignment mark structure comprises sidewalls and a bottom surface that are in direct contact with the molding compound die frame.

9. The device structure of claim 3, wherein the alignment mark structure is spaced from the molding compound die frame by a die attachment film including a polymer matrix layer and an adhesive layer.

10. A device structure comprising:
a fan-out package that comprises a molding compound die frame, at least one semiconductor die that is laterally surrounded by the molding compound die frame, and an organic interposer comprising redistribution dielectric layers embedding redistribution wiring interconnects and located on a first horizontal surface of the molding compound die frame; and
a packaging substrate that is bonded to bonding structures of the organic interposer,
wherein an alignment mark region including a localized recess region is located within an opening in a second horizontal surface of the molding compound die frame.

11. The device structure of claim 10, further comprising an additional semiconductor die overlying the fan-out package and attached to the fan-out package.

12. The device structure of claim 11, wherein:
the fan-out package comprises through-interposer via (TIV) structures that vertically extend through the molding compound die frame; and
the additional semiconductor die is bonded to the TIV structures through an array of solder material portions.

13. The device structure of claim 11, wherein the alignment mark region has an areal overlap with the additional semiconductor die and does not have any areal overlap with the at least one semiconductor die.

14. The device structure of claim 10, further comprising a lid structure that is attached to the packaging substrate and comprising a horizontal cap portion that overlies and covers an entirety of the at least one semiconductor die and the alignment mark region.

15. The device structure of claim 14, wherein:
an alignment mark structure is located within the localized recess region; and
the horizontal cap portion is in direct contact with the alignment mark structure or is attached to the alignment mark structure through an adhesive layer.

16. A method of forming a device structure, the method comprising:
forming an alignment mark structure over a carrier wafer;
disposing at least one semiconductor die over the carrier wafer using the alignment mark structure as a reference location for positioning the at least one semiconductor die;
forming a molding compound matrix around the at least one semiconductor die and over the alignment mark structure; and
forming a fan-out package by dicing the molding compound matrix, wherein the fan-out package comprises the at least one semiconductor die, the alignment mark structure, and a molding compound die frame that is a cut portion of the molding compound matrix.

17. The method of claim 16, wherein the alignment mark structure is formed by depositing and patterning a layer stack of a plurality of metallic material layers.

18. The method of claim 16, wherein the alignment mark structure is formed by depositing and patterning a dielectric material layer such that a sidewall of the alignment mark structure has a taper angle in a range from 1 degree to 20 degrees with respect to a vertical direction.

19. The method of claim 16, further comprising conformally forming a die attachment film over the alignment mark structure and above the carrier wafer, wherein the at least one semiconductor die is disposed over the die attachment film.

20. The method of claim 16, further comprising:
detaching the carrier wafer from an assembly comprising the molding compound matrix, the at least one semiconductor die, and the alignment mark structure; and
removing the alignment mark structure selective to a material of the molding compound matrix.
